(19) United States
(12) Patent Application Publication
(10) Pub. No.: US 2025/0151543 A1
(43) Pub. Date: May 8, 2025

(54) Display Substrate, Preparation Method therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Rong WANG, Beijing (CN); Yi HE, Beijing (CN); Cong FAN, Beijing (CN); Fan HE, Beijing (CN); Xiangdan DONG, Beijing (CN)

(21) Appl. No.: 18/691,049

(22) PCT Filed: Sep. 28, 2022
(86) PCT No.: PCT/CN2022/122260

§ 371 Date: Mar. 12, 2024

(51) Int. Cl. H10K 59/131; H10K 59/12; H10K 59/121

(52) U.S. Cl. CPC H10K 59/131; H10K 59/1201; H10K 59/1213

(57) ABSTRACT

Disclosed are a display substrate and a preparation method therefor, and a display apparatus. The display substrate includes a fanout region, the fanout region includes a first transition region, an isolation dam region, and a second transition region. The fanout region includes a gate metal layer and a source-drain metal layer, the gate metal layer includes any one or more of following: a first gate metal layer, a second gate metal layer, and a third gate metal layer. The gate metal layer is provided with a power supply connection line, the source-drain metal layer is provided with a first power supply line, the first power supply line is disposed in the first transition region and the second transition region, a first power supply line of the first transition region and a first power supply line of the second transition region are interconnected through the power supply connection line.

### CROSS-REFERENCE TO RELATED APPLICATION

The present application is a U.S. National Phase Entry of International Application No. PCT/CN2022/122260 having an international filing date of Sep. 28, 2022, contents of the above-identified application should be interpreted as being incorporated into the present application by reference.

### TECHNICAL FIELD

The present disclosure relates to, but is not limited to, the field of display technologies, and in particular to a display substrate, a preparation method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, and an extremely high response speed. With continuous development of display technologies, a display apparatus in which an OLED or a QLED is used as a light emitting device and a Thin Film Transistor (TFT) is used for signal control has become a mainstream product in the field of display at present.

### SUMMARY

The following is a summary of subject matter described herein in detail. The summary is not intended to limit the scope of protection of claims.

In one aspect, the present disclosure provides a display substrate including a display region and a bonding region located at a side of the display region, and the bonding region at least includes a fanout region and a bending region, the fanout region is located between the display region and the bending region, the fanout region at least includes a first transition region, an isolation dam region, and a second transition region disposed along a direction away from the display region; the fanout region includes a bonding structure layer disposed on a base substrate, the bonding structure layer at least includes a gate metal layer and a source-drain metal layer disposed at a side of the gate metal layer away from the base substrate, the gate metal layer includes any one or more of following: a first gate metal layer, a second gate metal layer, and a third gate metal layer, the source-drain metal layer includes any one or more of following: a first source-drain metal layer and a second source-drain metal layer, and a power supply connection line is disposed in the gate metal layer, a first power supply line is disposed in the source-drain metal layer, the power supply connection line is disposed in the first transition region, the isolation dam region, and the second transition region, the first power supply line is disposed in the first transition region and the second transition region, a first power supply line of the first transition region and a first power supply line of the second transition region are interconnected through the power supply connection line.

In an exemplary implementation mode, the bonding structure layer further includes a first planarization layer disposed at a side of the first source-drain metal layer away from the base substrate, the first power supply line is disposed at a side of the first planarization layer away from the base substrate, the first source-drain metal layer is provided with a first lap electrode and a second lap electrode, the first lap electrode is disposed in the first transition region, the second lap electrode is disposed in the second transition region, the first power supply line of the first transition region is connected with the first lap electrode, the first lap electrode is connected with a side of the power supply connection line close to the display region, the first power supply line of the second transition region is connected with the second lap electrode, and the second lap electrode is connected with a side of the power supply connection line away from the display region.

In an exemplary implementation mode, the bonding structure layer further includes an inorganic insulation layer disposed at a side of the power supply connection line away from the base substrate, the inorganic insulation layer is provided with a first connection opening and a second connection opening, the first lap electrode is connected with the side of the power supply connection line close to the display region through the first connection opening, and the second lap electrode is connected with the side of the power supply connection line away from the display region through the second connection opening.

In an exemplary implementation mode, a third connection opening is disposed on the first planarization layer, and the first power supply line of the first transition region is connected with the first lap electrode through the third connection opening.

In an exemplary implementation mode, the first planarization layer is provided with a first partition slot, an orthographic projection of the first partition slot on the base substrate contains an orthographic projection of the isolation dam region on the base substrate, the first planarization layer at a side of the first partition slot close to the display region covers an edge of the first lap electrode at a side close to the display region, the first planarization layer at a side of the first partition slot away from the display region covers an edge of the second lap electrode at a side away from the display region, the first partition slot exposes a surface of the first lap electrode at a side away from the display region, a surface of the second lap electrode at a side close to the display region, and a surface of the inorganic insulation layer located between the first lap electrode and the second lap electrode.

In an exemplary implementation mode, the first power supply line of the first transition region is lapped with the first lap electrode exposed in the first partition slot.

In an exemplary implementation mode, the first power supply line of the first transition region covers an edge of the first lap electrode at a side away from the display region.

In an exemplary implementation mode, the first power supply line of the second transition region is lapped with the second lap electrode exposed in the first partition slot.

In an exemplary implementation mode, the first power supply line of the second transition region covers an edge of the second lap electrode at a side close to the display region.

In an exemplary implementation mode, the bonding structure layer further includes a second planarization layer disposed at a side of the second source-drain metal layer away from the base substrate, the second planarization layer is provided with a second partition slot, an orthographic projection of the second partition slot on the base substrate contains an orthographic projection of the isolation dam region on the base substrate, the second planarization layer at a side of the second partition slot close to the display region covers an edge of the first power supply line of the first transition region at a side away from the display region, and the second planarization layer at a side of the second partition slot away from the display region covers an edge of the first power supply line of the second transition region at a side close to the display region.

In an exemplary implementation mode, the isolation dam region is provided with at least one isolation dam and at least one partition slot, the isolation dam is disposed at a side of the inorganic insulation layer away from the display region, the partition slot is disposed at a side of the isolation dam close to the display region or at a side of the isolation dam away from the display region, and the partition slot exposes a surface of the inorganic insulation layer.

In an exemplary implementation mode, on a plane perpendicular to the display substrate, the display substrate at least includes a first gate metal layer, a second gate metal layer, a third gate metal layer, a first source-drain metal layer, and a second source-drain metal layer that are sequentially disposed on the base substrate, the power supply connection line is disposed in one or more of the first gate metal layer, the second gate metal layer, and the third gate metal layer, and the first power supply line is disposed in the second source-drain metal layer.

In an exemplary implementation mode, on a plane perpendicular to the display substrate, the display substrate at least includes a first gate metal layer, a second gate metal layer, a third gate metal layer, and a first source-drain metal layer that are sequentially disposed on the base substrate, the power supply connection line is disposed in one or more of the first gate metal layer, the second gate metal layer, and the third gate metal layer, and the first power supply line is disposed in the first source-drain metal layer.

In another aspect, the present disclosure also provides a display apparatus, including the display substrate described above.

In yet another aspect, the present disclosure also provides a preparation method of a display substrate, wherein the display substrate includes a display region and a bonding region located at a side of the display region, the bonding region at least includes a fanout region and a bending region, the fanout region is located between the display region and the bending region, and the fanout region at least includes a first transition region, an isolation dam region, and a second transition region disposed along a direction away from the display region; the preparation method includes: forming a bonding structure layer on a base substrate of the fanout region, wherein the bonding structure layer at least includes a gate metal layer and a source-drain metal layer disposed at a side of the gate metal layer away from the base substrate, the gate metal layer includes any one or more of following: a first gate metal layer, a second gate metal layer, and a third gate metal layer, the source-drain metal layer includes any one or more of following: a first source-drain metal layer and a second source-drain metal layer, and a power supply connection line is disposed in the gate metal layer, a first power supply line is disposed in the source-drain metal layer, the power supply connection line is disposed in the first transition region, the isolation dam region, and the second transition region, the first power supply line is disposed in the first transition region and the second transition region, a first power supply line of the first transition region and a first power supply line of the second transition region are connected with each other through the power supply connection line.

Other aspects may be comprehended upon reading and understanding drawings and detailed description.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display substrate according to the present disclosure.

FIG. 2 is a schematic diagram of a structure of a display substrate.

FIG. 3 is a schematic diagram of a planar structure of a display region in a display substrate.

FIG. 4 is a schematic diagram of a sectional structure of a display region in a display substrate.

FIG. 5 is a schematic diagram of an equivalent circuit of a pixel drive circuit.

FIG. 6 is a schematic diagram of a planar structure of a fanout region in a bonding region.

FIG. 7 is a schematic diagram of a structure of a display substrate according to an exemplary embodiment of the present disclosure.

FIG. 8 is a schematic diagram after forming a pattern of a first semiconductor layer according to an embodiment of the present disclosure.

FIG. 9 is a schematic diagram after forming a pattern of a first conductive layer according to an embodiment of the present disclosure.

FIG. 10 is a schematic diagram after forming a pattern of a second conductive layer according to an embodiment of the present disclosure.

FIG. 11 is a schematic diagram after forming a pattern of a second semiconductor layer according to an embodiment of the present disclosure.

FIG. 12 is a schematic diagram after forming a pattern of a third conductive layer according to an embodiment of the present disclosure.

FIG. 13 is a schematic diagram after forming a pattern of a sixth insulation layer according to an embodiment of the present disclosure.

FIG. 14 is a schematic diagram after forming a pattern of a fourth conductive layer according to an embodiment of the present disclosure.

FIG. 15 is a schematic diagram after forming a pattern of a first planarization layer according to an embodiment of the present disclosure.

FIG. 16 is a schematic diagram after forming a pattern of a fifth conductive layer according to an embodiment of the present disclosure.

FIG. 17 is a schematic diagram after forming a pattern of a second planarization layer according to an embodiment of the present disclosure.

FIG. 18 is a schematic diagram after forming patterns of an anode conductive layer and a pixel definition layer according to an embodiment of the present disclosure.

FIG. 19 is a schematic diagram after forming patterns of an organic emitting layer and a cathode according to an embodiment of the present disclosure.

FIG. 20 is a schematic diagram showing that a Growing Dark Spot (GDS) defect occurs on a display substrate.

FIG. 21 is a schematic diagram of a structure of another display substrate according to an exemplary embodiment of the present disclosure.

FIG. 22 is a schematic diagram of a structure of yet another display substrate according to an exemplary embodiment of the present disclosure.

FIG. 23 is a schematic diagram of a structure of yet another display substrate according to an exemplary embodiment of the present disclosure.

FIG. 24 is a schematic diagram of a structure of yet another display substrate according to an exemplary embodiment of the present disclosure.

FIG. 25 is a schematic diagram of a structure of yet another display substrate according to an exemplary embodiment of the present disclosure.

Reference signs are described as follows.

| | | |
|---|---|---|
| 10-base substrate; | 11-first insulation layer; | 12-second insulation layer; |
| 13-third insulation layer; | 14-fourth insulation layer; | 15-fifth insulation layer; |
| 16-sixth insulation layer; | 17-first planarization layer; | 18-second planarization layer; |
| 20-first transistor; | 21-first active layer; | 22-first gate electrode; |
| 23-first source electrode; | 24-first drain electrode; | 30-second transistor; |
| 31-second active layer; | 32-second gate electrode; | 33-second source electrode; |
| 34-second drain electrode; | 40-storage capacitor; | 41-first electrode plate; |
| 42-second electrode plate; | 50-bonding structure layer; | 51-shielding layer; |
| 52-anode connection | 60-power supply connection | 61-first lap electrode; |
| electrode; | line; | |
| 62-second lap electrode; | 71-first connection opening; | 72-second connection |
| | | opening; |
| 73-third connection opening; | 81-first partition slot; | 82-second partition slot; |
| 91-anode; | 92-pixel definition layer; | 93-organic emitting layer; |
| 94-cathode; | 95-first encapsulation layer; | 96-second encapsulation |
| | | layer; |
| 97-third encapsulation layer; | 100-display region; | 102-drive circuit layer; |
| 103-light emitting structure | 104-encapsulation structure | 110-first power supply line; |
| layer; | layer; | |
| 120-second power supply | 200-bonding region; | 201-fanout region; |
| line; | | |
| 211-first transition region; | 212-second transition region; | 213-isolation dam region; |
| 300-bezel region; | 310-first isolation slot; | 320-second isolation slot; |
| 330-third isolation slot; | 340-fourth isolation slot; | 401-first dam foundation; |
| 402-second dam foundation; | 403-third dam foundation; | 404-fourth dam foundation; |
| 405-fifth dam foundation; | 410-first isolation dam; | 420-second isolation dam. |

### DETAILED DESCRIPTION

To make the objectives, technical solutions, and advantages of the present disclosure clearer, the embodiments of the present disclosure will be described in detail below in combination with the accompany drawings. It is to be noted that the implementation modes may be implemented in a plurality of different forms. Those of ordinary skill in the art may easily understand such a fact that modes and contents may be transformed into various forms without departing from the purpose and scope of the present disclosure. Therefore, the present disclosure should not be explained as being limited to contents recorded in following implementation modes only. The embodiments in the present disclosure and features in the embodiments may be randomly combined with each other in case of no conflict.

Scales of the drawings in the present disclosure may be used as a reference in actual processes, but are not limited thereto. For example, a width-length ratio of a channel, a thickness and a pitch of each film layer, and a width and a pitch of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set to avoid confusion of constituent elements, not to limit a quantity.

In the specification, for convenience, expressions “central”, “above”, “below”, “front”, “back”, “vertical”, “horizontal”, “top”, “bottom”, “inside”, “outside”, etc., indicating orientations or positional relationships are used for illustrating positional relationships between constituent elements with reference to the drawings, only for convenience of describing the specification and simplifying the description, do not indicate or imply that a referred apparatus or element must have a specific orientation and be structured and operated in the specific orientation, and thus should not be understood as limitations on the present disclosure. The positional relationships between the constituent elements may be changed as appropriate according to a direction where each constituent element is described. Therefore, appropriate replacements may be made according to situations, not limited to the expressions described in the specification.

In the specification, unless otherwise specified and defined, terms “mounting”, “mutual connection”, and “connection” should be generally understood. For example, it may be a fixed connection, or a detachable connection, or an integral connection. It may be a mechanical connection or an electrical connection. It may be a direct connection, or an indirect connection through an intermediate, or communication inside two elements. Those of ordinary skill in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. It is to be noted that in the specification, the channel region refers to a region where a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current is changed during work of a circuit, or the like, functions of the “source electrode” and the “drain electrode” may sometimes interchanged. Therefore, the “source electrode” and the “drain electrode” may be interchanged in the specification.

In the specification, an “electrical connection” includes a case that constituent elements are connected together through an element with a certain electrical action. “An element with a certain electrical action” is not particularly limited as long as electrical signals between the connected constituent elements may be sent and received. Examples of “an element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

A triangle, rectangle, trapezoid, pentagon, or hexagon, etc. in this specification are not strictly defined, and it may be an approximate triangle, rectangle, trapezoid, pentagon, or hexagon, etc. There may be some small deformations caused by tolerance, and there may be a chamfer, an arc edge, deformation, etc.

In the present disclosure, “about” refers to that a boundary is not defined so strictly and numerical values within process and measurement error ranges are allowed.

FIG. 1 is a schematic diagram of a structure of a display apparatus. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, wherein i and j may be natural numbers. At least one sub-pixel Pxij may include a circuit unit and a light emitting unit connected with the circuit unit, wherein the circuit unit may at least include a pixel drive circuit, and the pixel drive circuit is connected with a scan signal line, a light emitting signal line, and a data signal line, respectively. In an exemplary implementation mode, the timing controller may provide a grayscale value and a control signal suitable for a specification of the data signal driver to the data signal driver, may provide a clock signal, a scan start signal, etc. suitable for a specification of the scan driver to the scan driver, and may provide a clock signal, an emission stop signal, etc. suitable for a specification of the light emitting driver to the light emitting driver. The data driver may generate a data voltage to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signal to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting a scan start signal provided in a form of an on-level pulse to a next-stage circuit under control of the clock signal, wherein m may be a natural number. The light emitting driver may generate an emission signal to be provided to the light emitting signal lines E1, E2, E3, . . . , and Eo by receiving a clock signal, an emission stop signal, etc., from the timing controller. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

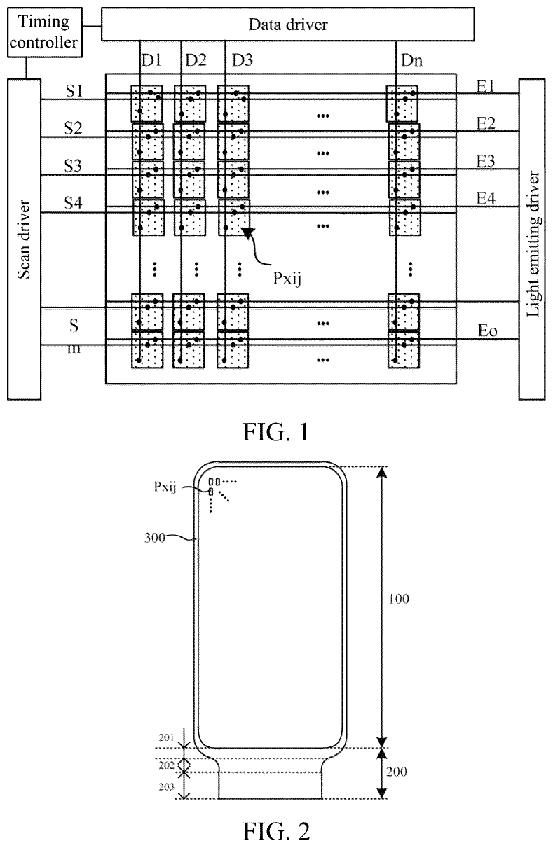

FIG. 2 is a schematic diagram of a structure of a display substrate. As shown in FIG. 2, the display substrate may include a display region 100, a bonding region 200 located at a side of the display region 100, and a bezel region 300 located at another side of the display region 100. In an exemplary implementation mode, the display region 100 may be a plat region, including a plurality of sub-pixels Pxij that constitute a pixel array, wherein the plurality of sub-pixels Pxij are configured to display a dynamic picture or a static image, and the display region 100 may be referred to as an Active Area (AA). In an exemplary implementation mode, the display substrate may be a flexible substrate, so that the display substrate may be deformable, for example, curled, bent, folded, or rolled.

In an exemplary implementation mode, the bonding region 200 may include a fanout region 201, a bending region 202, and a drive chip region 203 disposed along a direction away from the display region, wherein the fanout region 201 may at least include data transmission lines, and a plurality of data transmission lines are configured to connect a data signal line of the display region. The bending region 202 may at least include a bending groove configured to enable the drive chip region 203 to be bent to a back of the display region. The drive chip region may at least include an Integrated Circuit (IC) and a plurality of pins (PIN), the integrated circuit is configured to be connected with a plurality of data transmission lines, and the plurality of pins are configured to be bonded and connected with an external Flexible Printed Circuit (FPC).

In an exemplary implementation mode, the bezel region 300 may include a circuit region, a power supply line region, and a crack dam region, and a cutting region which are disposed along the direction away from the display region. The circuit region may at least include a plurality of cascaded gate drive circuits, the gate drive circuits are connected with a plurality of scan lines in the display region. The power supply line region may at least include a bezel power supply lead line, and the bezel power supply lead line extends along a direction parallel to an edge of the display region and is connected with a cathode in the display region. The crack dam region may at least include a plurality of cracks, and the cutting region may at least include a cutting groove, and the cutting groove is configured such that after preparation of all film layers of the display substrate is completed, a cutting device cuts along the cutting groove.

In an exemplary implementation mode, the fanout region in the bonding region 200 and the power supply line region in the bezel region 300 may be provided with a first isolation dam and a second isolation dam, the first isolation dam and the second isolation dam may extend along the direction parallel to the edge of the display region, thus forming an annular structure surrounding the display region, wherein the edge of the display region is an edge at a side of the display region, the bonding region, or the bezel region.

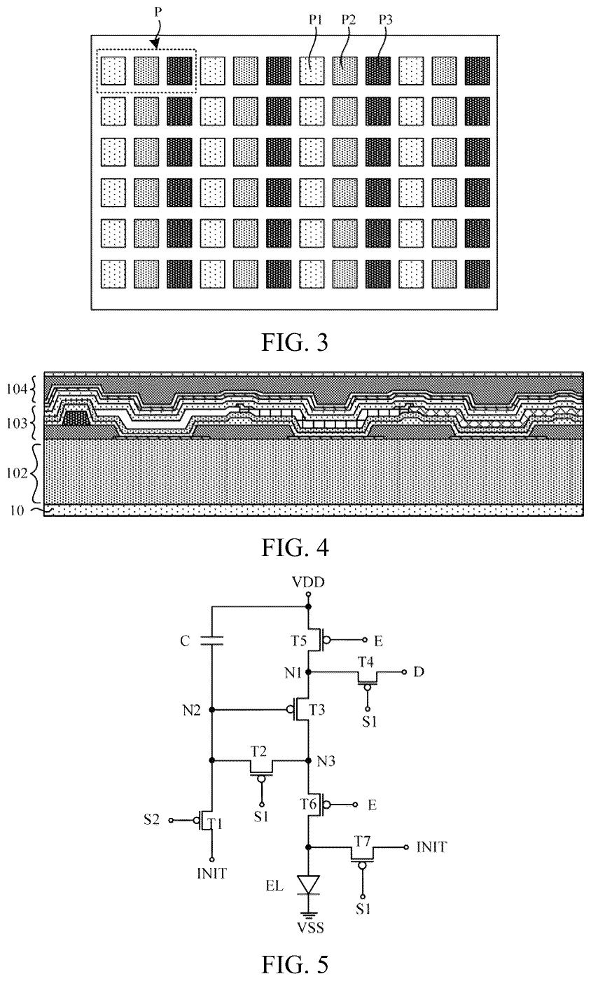

FIG. 3 is a schematic diagram of a planar structure of a display region in a display substrate. As shown in FIG. 3, the display region may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting unit, wherein the circuit unit may at least include a pixel drive circuit, the pixel drive circuit is connected with a scan signal line, a data signal line, and a light emitting signal line, respectively, and is configured to receive a data voltage transmitted by the data signal line and output a corresponding current to the light emitting unit under control of the scan signal line and the light emitting signal line. The light emitting unit of each sub-pixel may at least include a light emitting device, the light emitting device is connected with a pixel drive circuit of a sub-pixel where the light emitting device is located, and is configured to emit light with corresponding brightness in response to a current output by the pixel drive circuit of the sub-pixel where the light emitting device is located.

In an exemplary implementation mode, the first sub-pixel P1 may be a green (G) sub-pixel emitting green light, the second sub-pixel P2 may be a blue (B) sub-pixel emitting blue light, and the third sub-pixel P3 may be a red (R) sub-pixel emitting red light. In an exemplary implementation mode, a sub-pixel may be in a shape of a rectangle, a rhombus, a pentagon, or a hexagon. Three sub-pixels may be arranged in a manner to stand side by side horizontally, in a manner to stand side by side vertically, or in a manner like a Chinese character “ [symbol] ”, etc., which is not limited here in the present disclosure.

In an exemplary implementation mode, a pixel unit may include four sub-pixels, and the four sub-pixels may be arranged in a manner to stand side by side horizontally, in a manner to stand side by side vertically, or in a manner to form a square, which is not limited here in the present disclosure.

FIG. 4 is a schematic diagram of a sectional structure of a display region in a display substrate, illustrating a structure of three sub-pixels in the display region. As shown in FIG. 4, on a plane perpendicular to the display substrate, the display substrate may include a drive circuit layer 102 disposed on a base substrate 10, a light emitting structure layer 103 disposed at a side of the drive circuit layer 102 away from the base substrate 10, and an encapsulation structure layer 104 disposed at a side of the light emitting structure layer 103 away from the base substrate 10. In some possible implementation modes, the display substrate may include another film layer, such as a touch structure layer, which is not limited here in the present disclosure.

In an exemplary implementation mode, the base substrate 10 may be a flexible base substrate, or may be a rigid base substrate. The drive circuit layer 102 may include a plurality of circuit units, and a circuit unit may at least include a pixel drive circuit. The light emitting structure layer 103 may include a plurality of light emitting units, and a light emitting unit may at least include an anode, an organic emitting layer, and a cathode. The anode is connected with a pixel drive circuit. The organic emitting layer is connected with the anode. The cathode is connected with the organic emitting layer. The organic emitting layer emits light of a corresponding color under drive of the anode and the cathode. The encapsulation structure layer 104 may at least include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer to form a laminated structure of an inorganic material/an organic material/an inorganic material, which may ensure that external water vapor cannot enter the light emitting structure layer 103.

FIG. 5 is a schematic diagram of an equivalent circuit of a pixel drive circuit. In an exemplary implementation mode, the pixel drive circuit may have a structure of 3T1C, 4T1C, 5T1C, 5T2C, 6T1C, 7T1C, or 8T1C. As shown in FIG. 5, the pixel drive circuit may include seven transistors (a first transistor T1 to a seventh transistor T7) and one storage capacitor C. The pixel drive circuit is respectively connected with six signal lines (a data signal line D, a first scan signal line S1, a second scan signal line S2, a light emitting signal line E, a first power supply line VDD, and an initial signal line INIT).

In an exemplary implementation mode, the pixel drive circuit may include a first node N1, a second node N2, and a third node N3. Among them, the first node N1 is connected with a first electrode of the third transistor T3, a second electrode of the fourth transistor T4, and a second electrode of the fifth transistor T5, respectively. The second node N2 is connected with a second electrode of the first transistor, a first electrode of the second transistor T2, a gate electrode of the third transistor T3, and a first terminal of the storage capacitor C, respectively. The third node N3 is connected with a second electrode of the second transistor T2, a second electrode of the third transistor T3, and a first electrode of the sixth transistor T6, respectively.

In an exemplary implementation mode, the first terminal of the storage capacitor C is connected with the second node N2, and a second terminal of the storage capacitor C is connected with the first power supply line VDD.

In an exemplary implementation mode, a gate electrode of the first transistor T1 is connected with the second scan signal line S2, a first electrode of the first transistor T1 is connected with the initial signal line INIT, and the second electrode of the first transistor is connected with the second node N2. When a scan signal with an on level is applied to the second scan signal line S2, the first transistor T1 transmits a first initialization voltage to the gate electrode of the third transistor T3 so as to initialize a charge amount of the gate electrode of the third transistor T3.

In an exemplary implementation mode, a gate electrode of the second transistor T2 is connected with the first scan signal line S1, the first electrode of the second transistor T2 is connected with the second node N2, and the second electrode of the second transistor T2 is connected with the third node N3. When a scan signal with an on level is applied to the first scan signal line S1, the second transistor T2 enables the gate electrode of the third transistor T3 to be connected with the second electrode.

The gate electrode of the third transistor T3 is connected with the second node N2, namely the gate electrode of the third transistor T3 is connected with the first terminal of the storage capacitor C, the first electrode of the third transistor T3 is connected with the first node N1, and the second electrode of the third transistor T3 is connected with the third node N3. The third transistor T3 may be referred to as a drive transistor, and the third transistor T3 determines an amount of a drive current flowing between the first power supply line VDD and the second power supply line VSS according to a potential difference between the gate electrode and the first electrode of the third transistor T3.

A gate electrode of the fourth transistor T4 is connected with the first scan signal line S1, a first electrode of the fourth transistor T4 is connected with the data signal line D, and the second electrode of the fourth transistor T4 is connected with the first node N1. The fourth transistor T4, may be referred to as a switching transistor, a scan transistor, etc., and the fourth transistor T4 enables a data voltage of the data signal line D to be input into the pixel drive circuit when a scan signal with an on level is applied to the first scan signal line S1.

A gate electrode of the fifth transistor T5 is connected with the light emitting signal line E, a first electrode of the fifth transistor T5 is connected with the first power supply line VDD, and the second electrode of the fifth transistor T5 is connected with the first node N1. A gate electrode of the sixth transistor T6 is connected with the light emitting signal line E, the first electrode of the sixth transistor T6 is connected with the third node N3, and a second electrode of the sixth transistor T6 is connected with a first electrode of a light emitting device EL. The fifth transistor T5 and the sixth transistor T6 may be referred to as light emitting transistors. When a light emitting signal with an on level is applied to the light emitting signal line E, the fifth transistor T5 and the sixth transistor T6 enable the light emitting device to emit light by forming a drive current path between the first power supply line VDD and the second power supply line VSS.

A gate electrode of the seventh transistor T7 is connected with the first scan signal line S1, a first electrode of the seventh transistor T7 is connected with the initial signal line INIT, and a second electrode of the seventh transistor T7 is connected with the first electrode of the light emitting device EL. When a scan signal with an on level is applied to the first scan signal line S1, the seventh transistor T7 transmits a second initial voltage to the first electrode of the light emitting device so as to initialize a charge amount accumulated in the first electrode of the light emitting device EL or release a charge amount accumulated in the first electrode of the light emitting device.

In an exemplary implementation mode, a light emitting unit EL may be an OLED, including a first electrode (anode), an organic emitting layer, and a second electrode (cathode) which are stacked, or may be a QLED, including a first electrode (anode), a quantum dot emitting layer, and a second electrode (cathode) which are stacked.

In an exemplary implementation mode, a second electrode of the light emitting unit EL is connected with the second power supply line VSS, a signal of the second power supply line VSS is a low-level signal continuously provided, and a signal of the first power supply line VDD is a high-level signal continuously provided.

In an exemplary implementation mode, the first transistor T1 to the seventh transistor T7 may be P-type transistors, or may be N-type transistors. Use of a same type of transistors in a pixel drive circuit may simplify a process flow, reduce a process difficulty of a display panel, and improve a yield of products. In some possible implementation modes, the first transistor T1 to the seventh transistor T7 may include a P-type transistor and an N-type transistor.

In an exemplary implementation mode, for the first transistor T1 to the seventh transistor T7, low temperature poly silicon thin film transistors may be adopted, or oxide thin film transistors may be adopted, or a low temperature poly silicon thin film transistor and an oxide thin film transistor may be adopted. An active layer of a low temperature poly silicon thin film transistor may be made of Low Temperature Poly Silicon (LTPS for short), and an active layer of an oxide thin film transistor may be made of an oxide semiconductor (Oxide). The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display substrate to form a Low Temperature Polycrystalline Oxide (LTPO) display substrate, so that advantages of both the low temperature poly silicon thin film transistor and the oxide thin film transistor may be utilized, low-frequency drive may be achieved, power consumption may be reduced, and display quality may be improved.

In an exemplary implementation mode, taking a case that the seven transistors in the pixel drive circuit shown in FIG. 5 are all P-type transistors as an example, a working process of the pixel drive circuit may include following stages.

In a first stage, referred to as a reset stage, a signal of the second scan signal line S2 is a low-level signal, and signals of the first scan signal line S1 and the light emitting signal line E are high-level signals. The signal of the second scan signal line S2 is the low-level signal, so that the first transistor T1 is turned on, and a signal of the initial signal line INIT is provided to the second node N2 to initialize the storage capacitor C to clear an original data voltage in the storage capacitor. The signals of the first scan signal line S1 and the light emitting signal line E are the high-level signals, so that the second transistor T2, the fourth transistor T4, the fifth transistor T5, the sixth transistor T6, and the seventh transistor T7 are turned off. An OLED does not emit light in this stage.

In a second stage, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the first terminal of the storage capacitor C is at a low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second terminal (the second node N2) of the storage capacitor C is Vd−|Vth|, wherein Vd is the data voltage output by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization and ensuring that the OLED does not emit light. A signal of the second scan signal line S2 is a high-level signal, so that the first transistor T1 is turned off. A signal of the light emitting signal line E is a high-level signal, so that the fifth transistor T5 and the sixth transistor T6 are turned off.

In a third stage, referred to as a light emitting stage, a signal of the light emitting signal line E is a low-level signal, and signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between the gate electrode and the first electrode of the third transistor T3. Since the voltage of the second node N2 is Vd−|Vth|, the drive current of the third transistor T3 is as follows.

$$I = K * {( V gs - V th )}^{2} = K * {[ ( V dd - V d + \vert V th \vert ) - V th ]}^{2} = K * {[ ( V dd - V d ]}^{2}$$

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

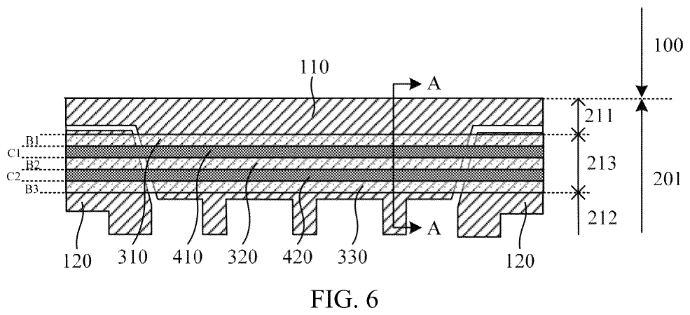

FIG. 6 is a schematic diagram of a planar structure of a fanout region in a bonding region. In an exemplary implementation mode, in a plane parallel to the display substrate, the bonding region may be located at a side of the display region, and the bonding region may at least include a fanout region 201 adjacent to the display region. As shown in FIG. 6, the fanout region 201 may be provided with at least a first power supply line 110, a second power supply line 120, and a plurality of data transmission lines (not shown). The plurality of data transmission lines are configured to connect a data signal line of the display region 100, the first power supply line 110 is connected with a high-voltage power supply line of the display region 100 and is configured to provide a high-voltage signal to a plurality of circuit units of the display region 100, the second power supply line 120 is connected with a low-voltage power supply line of the bezel region and is configured to provide a low-voltage signal to a plurality of light emitting units of the display region 100.

In an exemplary implementation mode, the fanout region 201 may at least include a first transition region 211, an isolation dam region 213, and a second transition region 212 arranged in sequence along a direction away from the display region 100. The first transition region 211 is connected to the display region 100 and is configured as a region where a cathode extends, the isolation dam region 213 is connected to the first transition region 211 and is configured as a region where an isolation dam and a partition slot are disposed, the second transition region 212 is connected to the isolation dam region 213 and is configured as a region outside an encapsulation structure.

In an exemplary implementation mode, a cathode in a light emitting structure layer is prepared using an Open Mask (OPM) to reduce a cost and increase production capacity. Generally, an opening on a cathode shadow will expose the display region and its peripheral region, so that the first transition region 211 of the fanout region 201 is formed with a cathode, and an edge of the cathode away from the display region is located in a middle region of the first transition region 211.

In an exemplary implementation mode, the isolation dam region 213 may at least include a first slot region B1, a first dam region C1, a second slot region B2, a second dam region C2, and a third slot region B3 sequentially disposed along a direction away from the display region 100. The first slot region B1 is configured to dispose a first isolation slot 310, the second slot region B2 is configured to dispose a second isolation slot 320, the third slot region B3 is configured to dispose a third isolation slot 330, the first dam region C1 is configured to dispose a first isolation dam 410, and the second dam region C2 is configured to dispose a second isolation dam 420.

In an exemplary implementation mode, a distance between the first isolation dam 410 and an edge of the display region 100 is less than a distance between the second isolation dam 420 and the edge of the display region 100. That is, the second isolation dam 420 is disposed at a side of the first isolation dam 410 away from the display region 100. The first isolation slot 310 may be disposed at a side of the first isolation dam 410 close to the display region, the second isolation slot 320 may be disposed between the first isolation dam 410 and the second isolation dam 420, and the third isolation slot 330 may be disposed at a side of the second isolation dam 420 away from the display region 100.

In an exemplary implementation mode, the first isolation dam 410 and the second isolation dam 420 may be of a dam structure stacked by a plurality of organic layers, and the first isolation dam 410 and the second isolation dam 420 are configured to avoid overflow of organic encapsulation layers. An organic layer within the first isolation slot 310, the second isolation slot 320, and the third isolation slot 330 are removed to expose a surface of the first power supply line 110 or the second power supply line 120 to improve an encapsulation effect of an inorganic encapsulation layer.

In an exemplary implementation mode, the first isolation dam 410, the second isolation dam 420, the first isolation slot 310, the second isolation slot 320, and the third isolation slot 330 may extend along a direction parallel to the edge of the display region, so as to form an annular structure surrounding the display region 100, and the edge of the display region is an edge of the display region at a side close to the bonding region or close to the bezel region.

Research shows that the first power supply line in the fanout region 201 will cause a short-circuit defect of a cathode. For a display substrate with a narrowed lower bezel, if a process margin of a cathode opening edge on a cathode shadow used for preparing the cathode is insufficient or a process parameter fluctuates greatly, an edge of the cathode will extend beyond the first transition region to a region where the first isolation slot 310 is located. Since the organic layer within the first isolation slot 310 is removed and the surface of the first power supply line 110 is exposed, the cathode extending to the first isolation slot 310 will be lapped with the first power supply line 110, resulting in short circuit of the cathode and poor display of the display substrate. Further research shows that edges of the first power supply line 110 and the second power supply line 120 in the fanout region 201 will also form a water vapor transmission path. If there is a gap or fracture in an encapsulation structure layer, water vapor in the atmosphere will enter the water vapor transmission path along the gap or fracture and invade a light emitting device. As the water vapor continuously invades the light emitting device along the water vapor transmission path, a failure region gradually expands, resulting in poor display of the display substrate, which is called a Growing Dark Spot (GDS).

The present disclosure provides a display substrate including a display region and a bonding region located at a side of the display region, and the bonding region at least includes a fanout region and a bending region, the fanout region is located between the display region and the bending region, the fanout region at least includes a first transition region, an isolation dam region, and a second transition region disposed along a direction away from the display region; the fanout region includes a bonding structure layer disposed on a base substrate, the bonding structure layer at least includes a gate metal layer and a source-drain metal layer disposed at a side of the gate metal layer away from the base substrate, the gate metal layer includes any one or more of following: a first gate metal layer, a second gate metal layer, and a third gate metal layer, the first gate metal layer, the second gate metal layer, and the third gate metal layer may be sequentially disposed along a direction away from the base substrate, the source-drain metal layer includes any one or more of following: a first source-drain metal layer and a second source-drain metal layer, the first source-drain metal layer and the second source-drain metal layer may be sequentially disposed along the direction away from the base substrate, and a power supply connection line is disposed in the gate metal layer, a first power supply line is disposed in the source-drain metal layer, the power supply connection line is disposed in the first transition region, the isolation dam region, and the second transition region, the first power supply line is disposed in the first transition region and the second transition region, the first power supply line of the first transition region and the first power supply line of the second transition region are connected with each other through the power supply connection line.

In an exemplary implementation mode, the bonding structure layer further includes a first planarization layer disposed at a side of the first source-drain metal layer away from the base substrate, the first power supply line is disposed at a side of the first planarization layer away from the base substrate, the first source-drain metal layer is provided with a first lap electrode and a second lap electrode, the first lap electrode is disposed in the first transition region, the second lap electrode is disposed in the second transition region, the first power supply line of the first transition region is connected with the first lap electrode, the first lap electrode is connected with a side of the power supply connection line close to the display region, the first power supply line of the second transition region is connected with the second lap electrode, and the second lap electrode is connected with a side of the power supply connection line away from the display region.

In an exemplary implementation mode, the bonding structure layer further includes an inorganic insulation layer disposed at a side of the power supply connection line away from the base substrate, the inorganic insulation layer is provided with a first connection opening and a second connection opening, the first lap electrode is connected with a side of the power supply connection line close to the display region through the first connection opening, and the second lap electrode is connected with a side of the power supply connection line away from the display region through the second connection opening.

In an exemplary implementation mode, the isolation dam region is provided with at least one isolation dam and at least one partition slot, the isolation dam is disposed at a side of the inorganic insulation layer away from the display region, and the partition slot is disposed at a side of the isolation dam close to the display region or at a side of the isolation dam away from the display region, and the partition slot exposes a surface of the inorganic insulation layer.

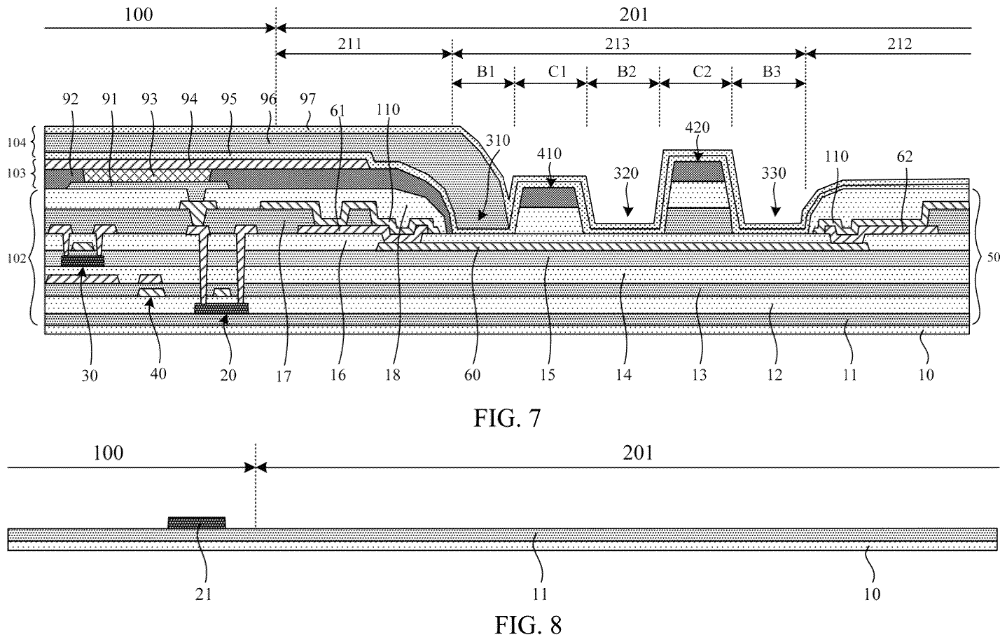

FIG. 7 is a schematic diagram of a structure of a display substrate according to an exemplary embodiment of the present disclosure, and is a cross-sectional structure taken along a direction A-A in FIG. 6. In a plane parallel to the display substrate, the display substrate may at least include a display region 100 and a fanout region 201 located at a side of the display region 100. As shown in FIG. 7, the fanout region 201 may at least include a first transition region 211, an isolation dam region 213, and a second transition region 212 that are sequentially disposed along a direction away from the display region 100. The isolation dam region 213 is configured to dispose at least one isolation dam and at least one partition slot.

In an exemplary implementation mode, the isolation dam region 213 may at least include a first slot region B1, a first dam region C1, a second slot region B2, a second dam region C2, and a third slot region B3 sequentially disposed along the direction away from the display region 100. The first slot region B1 is configured to dispose a first isolation slot 310, the second slot region B2 is configured to dispose a second isolation slot 320, the third slot region B3 is configured to dispose a third isolation slot 330, the first dam region C1 is configured to dispose a first isolation dam 410, and the second dam region C2 is configured to dispose a second isolation dam 420.

In an exemplary implementation mode, in a plane perpendicular to the display substrate, the display substrate 100 may at least include a drive circuit layer 102 disposed on a base substrate 10, a light emitting structure layer 103 disposed at a side of the drive circuit layer 102 away from the base substrate 10, and an encapsulation structure layer 104 disposed at a side of the light emitting structure layer 103 away from the base substrate 10.

In an exemplary implementation mode, the drive circuit layer 102 may at least include: a first insulation layer 11 disposed on the base substrate 10, a first semiconductor layer disposed at a side of the first insulation layer 11 away from the base substrate, a second insulation layer 12 disposed at a side of the first semiconductor layer away from the base substrate, a first gate metal layer disposed at a side of the second insulation layer 12 away from the base substrate, a third insulation layer 13 disposed at a side of the first gate metal layer away from the base substrate, a second gate metal layer disposed at a side of the third insulation layer 13 away from the base substrate, a fourth insulation layer 14 disposed at a side of the second gate metal layer away from the base substrate, a second semiconductor layer disposed at a side of the fourth insulation layer 14 away from the base substrate, a fifth insulation layer 15 disposed at a side of the second semiconductor layer away from the base substrate, a third gate metal layer disposed at a side of the fifth insulation layer 15 away from the base substrate, a sixth insulation layer 16 disposed at a side of the third gate metal layer away from the base substrate, a first source-drain metal layer disposed at a side of the sixth insulation layer 16 away from the base substrate, a first planarization layer 17 disposed at a side of the first source-drain metal layer away from the base substrate, a second source-drain metal layer disposed at a side of the first planarization layer away from the base substrate, and a second planarization layer 18 disposed at a side of the second source-drain metal layer away from the base substrate.

In an exemplary implementation mode, the first semiconductor layer may at least include a first active layer, the first gate metal layer may at least include a first gate electrode and a first electrode plate, the second gate metal layer may at least include a second electrode plate and a shielding layer, the second semiconductor layer may at least include a second active layer, the third gate metal layer may at least include a second gate electrode, the first source-drain metal layer may at least include a first source electrode, a first drain electrode, a second source electrode, and a second drain electrode, the second source-drain metal layer may at least include an anode connection electrode. The first active layer, the first gate electrode, the first source electrode, and the first drain electrode constitute a first transistor 20 of low temperature poly silicon, the second active layer, the second gate electrode, the second source electrode, and the second drain electrode constitute a second transistor 30 of an oxide, and the first electrode plate and the second electrode plate constitute a storage capacitor 40. In an exemplary implementation mode, the first transistor 20 may be a drive transistor of a pixel drive circuit, and the second transistor 30 may be a switching transistor of the pixel drive circuit.

In an exemplary implementation mode, the light emitting structure layer 103 may at least include an anode 91, a pixel definition layer 92, an organic emitting layer 93, and a cathode 94. The anode 91 is connected with the first drain electrode of the first transistor 20 through the anode connection electrode, the organic emitting layer 93 is connected with the anode 91, and the cathode 94 is connected with the organic emitting layer 93. The organic emitting layer 93 emits light of a corresponding color under drive of the anode 91 and the cathode 94.

In an exemplary implementation mode, the encapsulation structure layer 104 may at least include a first encapsulation layer 95, a second encapsulation layer 96, and a third encapsulation layer 97 that are stacked. The first encapsulation layer 95 and the third encapsulation layer 97 may be made of an inorganic material, and the second encapsulation layer 96 may be made of an organic material. The second encapsulation layer 96 is disposed between the first encapsulation layer 95 and the third encapsulation layer 97 to form a laminated structure of an inorganic material/an organic material/an inorganic material, which may ensure that external water vapor cannot enter the light emitting structure layer 103.

In an exemplary implementation mode, in a plane perpendicular to the display substrate, the fanout region 201 of the bonding region may at least include a bonding structure layer 50 disposed on the base substrate 10 and a composite encapsulation layer disposed at a side of the bonding structure layer 50 away from the base substrate.

In an exemplary implementation mode, the bonding structure layer 50 may at least include a gate metal layer and a source-drain metal layer disposed at a side of the gate metal layer away from the base substrate. The gate metal layer may at least include a third gate metal layer, the source-drain metal layer may at least include a first source-drain metal layer and a second source-drain metal layer, the third gate metal layer is provided with a power supply connection line 60, the first source-drain metal layer is provided with a first lap electrode 61 and a second lap electrode 62, and the second source-drain metal layer is provided with a first power supply line 110.

In an exemplary implementation mode, the bonding structure layer 50 may further include a first insulation layer 11, a second insulation layer 12, a third insulation layer 13, a fourth insulation layer 14, a fifth insulation layer 15, a sixth insulation layer 16, a first planarization layer 17, and a second planarization layer 18. The first insulation layer 11 is disposed on the base substrate 10, the second insulation layer 12 is disposed at a side of the first insulation layer 11 away from the base substrate, the third insulation layer 13 is disposed at a side of the second insulation layer 12 away from the base substrate, the fourth insulation layer 14 is disposed at a side of the third insulation layer 13 away from the base substrate, the fifth insulation layer 15 is disposed at a side of the fourth insulation layer 14 away from the base substrate, the power supply connection line 60 is disposed at a side of the fifth insulation layer 15 away from the base substrate, the sixth insulation layer 16 is disposed at a side of the power supply connection line 60 away from the base substrate, the first lap electrode 61 and the second lap electrode 62 are disposed at a side of the sixth insulation layer 16 away from the base substrate, the first planarization layer 17 is disposed at a side of the first lap electrode 61 and the second lap electrode 62 away from the base substrate, the first power supply line 110 is disposed at a side of the first planarization layer 17 away from the base substrate, and the second planarization layer 18 is disposed at a side of the first power supply line 110 away from the base substrate.

In an exemplary implementation mode, the power supply connection line 60 may be located in a partial region of the first transition region 211, an entire region of the isolation dam region 213, and a partial region of the second transition region 212, i.e., the power supply connection line 60 may extend from the first transition region 211 to the second transition region 212 through the isolation dam region 213.

In an exemplary implementation mode, the first power supply line 110 may be located in the first transition region 211 and the second transition region 212, respectively. The first lap electrode 61 may be located in the first transition region 211, and the second lap electrode 62 may be located in the second transition region 212, the first power supply line 110 of the first transition region 211 is connected with the first lap electrode 61, the first lap electrode 61 is connected with a side (a part located in the first transition region 211) of the power supply connection line 60 close to the display region, the first power supply line 110 of the second transition region 212 is connected with the second lap electrode 62, the second lap electrode 62 is connected with a side (a part located in the second transition region 212) of the power supply connection line 60 away from the display region, the first power supply line 210 crosses the isolation dam region 213 through the first lap electrode 61, the power supply connection line 60, and the second lap electrode 62, forming a first power supply line crossing the isolation dam region 213 through a transfer structure.

In an exemplary implementation mode, a first connection opening and a second connection opening may be disposed on the sixth insulation layer 16 covering the power supply connection line 60, the first lap electrode 61 may be connected with a side of the power supply connection line 60 close to the display region through the first connection opening, and the second lap electrode 62 may be connected with a side of the power supply connection line away from the display region through the second connection opening.

In an exemplary implementation mode, a third connection opening may be disposed on the first planarization layer 17 covering the first lap electrode 61, and the first power supply line 110 of the first transition region 211 may be connected with the first lap electrode 61 through the third connection opening.

In an exemplary implementation mode, the first planarization layer 17 may be provided with a first partition slot, and the first partition slot exposes a part of a surface of the first lap electrode 61 away from the display region, a part of a surface of the second lap electrode 62 close to the display region, and a surface of the sixth insulation layer 16 located between the first lap electrode 61 and the second lap electrode 62. An orthographic projection of the first partition slot on the base substrate contains an orthographic projection of the isolation dam region 213 on the base substrate.

In an exemplary implementation mode, the first planarization layer 17 at a side of the first partition slot close to the display region covers an edge of the first lap electrode 61 close to the display region, and the first planarization layer 17 at a side of the first partition slot away from the display region covers an edge of the second lap electrode 62 away from the display region.

In an exemplary implementation mode, the first power supply line 110 of the first transition region 211 is lapped with the first lap electrode 61 exposed in the first partition slot, and the first power supply line 110 of the first transition region 211 covers an edge of the first lap electrode 61 away from the display region.

In an exemplary implementation mode, the first power supply line 110 of the second transition region 212 is lapped with the second lap electrode 62 exposed in the first partition slot, and the first power supply line 110 of the second transition region 212 covers an edge of the second lap electrode 62 close to the display region.

In an exemplary implementation mode, the second planarization layer 18 may be provided with a second partition slot, an orthographic projection of the second partition slot on the base substrate may be located within a range of the orthographic projection of the first partition slot on the base substrate, and the orthographic projection of the second partition slot on the base substrate contains the orthographic projection of the isolation dam region 213 on the base substrate.

In an exemplary implementation mode, the second planarization layer 18 at a side of the second partition slot close to the display region may cover an edge of the first power supply line 110 of the first transition region 211 away from the display region, and the second planarization layer 18 at a side of the second partition slot away from the display region may cover an edge of the first power supply line 110 of the second transition region 212 close to the display region.

In an exemplary implementation mode, at least one isolation dam and at least one partition slot are disposed within the second partition slot, the isolation dam may be disposed at a side of the sixth insulation layer 16 away from the display region, the partition slot may be disposed at a side of the isolation dam close to the display region or away from the display region, and the partition slot exposes a surface of the sixth insulation layer 16.

In an exemplary implementation mode, a first isolation dam 410 located in the first dam region C1 and a second isolation dam 420 located in the second dam region C2 may be included within the second partition slot, a distance between the second isolation dam 420 and the display region 100 is greater than a distance between the first isolation dam 410 and the display region 100, and a distance between a surface of the second isolation dam 420 away from the base substrate and the base substrate is greater than a distance between a surface of the first isolation dam 410 away from the base substrate and the base substrate.

In an exemplary implementation mode, the second partition slot may include a first isolation slot 310 located in the first slot region B1, a second isolation slot 320 located in the second slot region B2, and a third isolation slot 330 located in the third slot region B3, i.e., the first isolation slot 310 is located at a side of the first isolation dam 410 close to the display region, the second isolation slot 320 is located between the first isolation dam 410 and the second isolation dam 420, and the third isolation slot 330 is located at a side of the second isolation dam 420 away from the display region. An organic material layer within the first isolation slot 310, the second isolation slot 320, and the third isolation slot 330 are removed to expose the sixth insulation layer 16, so that the first encapsulation layer 95 in the encapsulation structure layer is lapped with the sixth insulation layer 16 within the first isolation slot 310, the second isolation slot 320, and the third isolation slot 330, respectively.

In an exemplary implementation mode, the first isolation dam 410 may include a second dam foundation and a fourth dam foundation that are stacked. The second dam foundation and the second planarization layer may be disposed in a same layer and formed synchronously through a same patterning process. The fourth dam foundation and the pixel definition layer may be disposed in a same layer and formed synchronously through a same patterning process.

In an exemplary implementation mode, the second isolation dam 420 may include a first dam foundation a third dam foundation, and a fifth dam foundation that are stacked. The first dam foundation and the first planarization layer may be disposed in a same layer and formed synchronously through a same patterning process. The third dam foundation and the second planarization layer may be disposed in a same layer and formed synchronously through a same patterning process. The fifth dam foundation and the pixel definition layer may be disposed in a same layer and formed synchronously through a same patterning process.

In an exemplary implementation mode, the power supply connection line 60 of the fanout region 201 and the second gate electrode of the display region may be disposed in a same layer and formed synchronously through a same patterning process.

In an exemplary implementation mode, the first lap electrode 61 and the second lap electrode 62 of the fanout region 201 may be disposed in a same layer as the first source electrode, the first drain electrode, the second source electrode, and the second drain electrode of the display region, and they may be formed synchronously through a same patterning process.

In an exemplary implementation mode, the first power supply line 110 of the fanout region 201 and the anode connection electrode of the display region may be disposed in a same layer and formed synchronously through a same patterning process.

Exemplary description is made below through a preparation process of the display substrate according to the exemplary embodiment. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition; coating may be any one or more of spray coating, spin coating, and inkjet printing; and etching may be any one or more of dry etching and wet etching, which is not limited in present disclosure. A “thin film” refers to a layer of thin film made of a certain material on a base substrate using deposition, coating, or another process. If the “thin film” does not need a patterning process in an entire manufacturing process, the “thin film” may also be called a “layer”. If the “thin film” needs the patterning process in the entire manufacturing process, the “thin film” is called a “thin film” before the patterning process and is called a “layer” after the patterning process. At least one “pattern” is contained in the “layer” after the patterning process. “A and B are disposed in a same layer” in the present disclosure means that A and B are formed simultaneously through a same patterning process, and a “thickness” of a film layer is a size of the film layer in a direction perpendicular to a display substrate. In an exemplary implementation mode of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A is overlapped with the boundary of the orthographic projection of B.

In an exemplary implementation mode, the preparation process of the display substrate may include following operations.

(1) Forming a pattern of a first semiconductor layer. In an exemplary implementation mode, forming a pattern of a first semiconductor layer may include: sequentially depositing a first insulation thin film and a first semiconductor thin film on the base substrate 10, and patterning the first semiconductor thin film through a patterning process to form a first insulation layer 11 covering the entire base substrate 10 and the pattern of the first semiconductor layer disposed on the first insulation layer 11. The pattern of the first semiconductor layer may be disposed in the display region 100, and the pattern of the first semiconductor layer may at least include a first active layer 21, as shown in FIG. 8.

In an exemplary implementation mode, the patterning the first semiconductor thin film through the patterning process may include: forming an amorphous silicon (a-si) thin film on the first insulation thin film, dehydrogenating the amorphous silicon thin film, and crystallizing the dehydrogenated amorphous silicon thin film to form a poly silicon thin film. Subsequently, the poly silicon thin film is patterned to form the pattern of the first semiconductor layer. Since a large amount of hydrogen existing in amorphous silicon tend to cause a defect in a subsequent process, a process of removing hydrogen needs to be performed after the amorphous silicon thin film is formed. A crystallization process is a process for crystallizing amorphous silicon to form poly silicon (p-si). For example, the crystallization process may be performed through an Excimer Laser Annealing (ELA) process. Since an annealing process for forming poly silicon may damage an oxide, preparation of a first active layer of low temperature poly silicon is set before preparation of a second active layer of a metal oxide.

In an exemplary implementation mode, the first insulation layer may prevent substances in the base substrate from diffusing into other film layer structures in a subsequent process, which affects quality of the display substrate adversely.

In an exemplary implementation mode, after this patterning process, the fanout region 201 of the bonding region may include the first insulation layer 11 disposed on the base substrate 10.

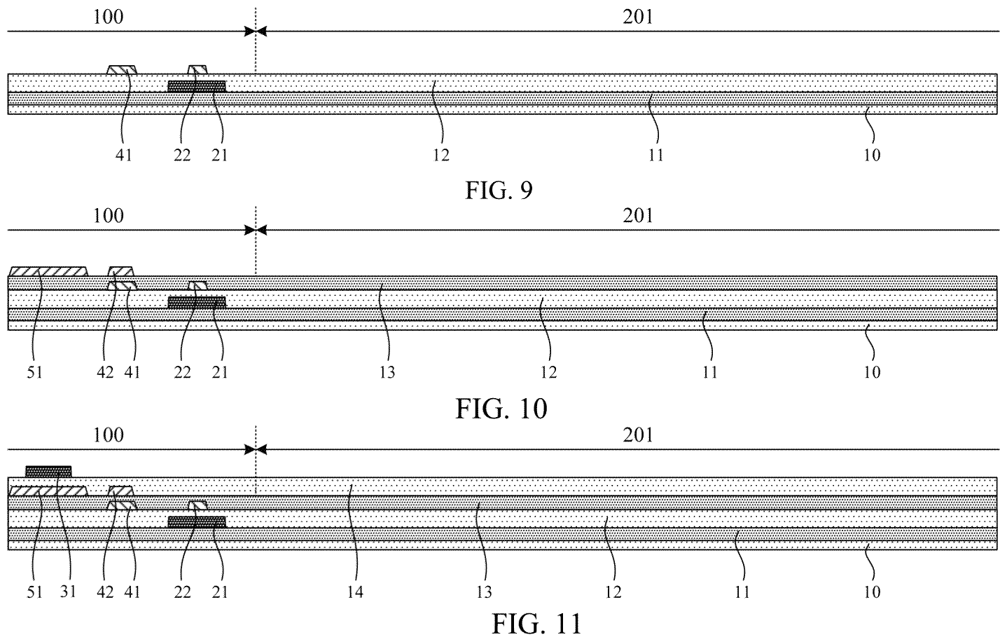

(2) Forming a pattern of a first conductive layer. In an exemplary implementation mode, forming a pattern of a first conductive layer may include: sequentially depositing a second insulation thin film and a first conductive thin film on the base substrate where the aforementioned pattern is formed, patterning the first conductive thin film through a patterning process to form a second insulation layer 12 covering the pattern of the first semiconductor layer and a pattern of a first conductive layer disposed on the second insulation layer 12, wherein the pattern of the first conductive layer may be disposed in the display region 100 and may at least include a first gate electrode 22 and a first electrode plate 41, as shown in FIG. 9. In an exemplary implementation mode, the first conductive layer may be referred to as a first gate metal (GATE1) layer.

In an exemplary implementation mode, an orthographic projection of the first gate electrode 22 on the base substrate may be located within a range of an orthographic projection of the first active layer 21 on the base substrate.

In an exemplary implementation mode, after this patterning process, the fanout region 201 of the bonding region may include the first insulation layer 11 and the second insulation layer 12 stacked on the base substrate 10.

(3) Forming a pattern of a second conductive layer. In an exemplary implementation mode, forming a pattern of a second conductive layer may include: sequentially depositing a third insulation thin film and a second conductive thin film on the base substrate where the aforementioned patterns are formed, patterning the second conductive thin film through a patterning process to form a third insulation layer 13 covering the pattern of the first conductive layer and a pattern of a second conductive layer disposed on the third insulation layer 13, wherein the pattern of the second conductive layer may be disposed in the display region 100, and the pattern of the second conductive layer may at least include a second electrode plate 42 and a shielding layer 51 as a shielding structure of a second transistor, as shown in FIG. 10. In an exemplary implementation mode, the second conductive layer may be referred to as a second gate metal (GATE2) layer.

In an exemplary implementation mode, an orthographic projection of the second electrode plate 42 on the base substrate is at least partially overlapped with an orthographic projection of the first electrode plate 41 on the base substrate, and the first electrode plate 41 and the second electrode plate 42 constitute a storage capacitor of a pixel drive circuit.

After this patterning process, the fanout region 201 of the bonding region may include the first insulation layer 11, the second insulation layer 12, and the third insulation layer 13 stacked on the base substrate 10.

(4) Forming a pattern of a second semiconductor layer. In an exemplary implementation mode, forming a pattern of a second semiconductor layer may include: sequentially depositing a fourth insulation thin film and a second semiconductor thin film on the base substrate where the aforementioned patterns are formed, and patterning the second semiconductor thin film through a patterning process to form a fourth insulation layer 14 covering the entire base substrate 10 and a pattern of a second semiconductor layer disposed on the fourth insulation layer 14. The pattern of the second semiconductor layer may be disposed in the display region 100 and the pattern of the second semiconductor layer at least includes a second active layer 31, as shown in FIG. 11.

In an exemplary implementation mode, an orthographic projection of the second active layer 31 on the base substrate may be located within a range of an orthographic projection of the shielding layer 51 on the base substrate.

In an exemplary implementation mode, the second semiconductor thin film may be made of an oxide, and the oxide may be any one or more of Indium Gallium Zinc Oxide (InGaZnO), Indium Gallium Zinc Oxynitride (InGaZnON), Zinc Oxide (ZnO), Zinc Oxynitride (ZnON), Zinc Tin Oxide (ZnSnO), Cadmium Tin Oxide (CdSnO), Gallium Tin Oxide (GaSnO), Titanium Tin Oxide (TiSnO), Copper Aluminum Oxide (CuAlO), Strontium Copper Oxide (SrCuO), Lanthanum Copper Oxysulfide (LaCuOS), Gallium Nitride (GaN), Indium Gallium Nitride (InGaN), Aluminum Gallium Nitride (AlGaN), and Indium Gallium Aluminum Nitride (InGaAlN). In some possible implementation modes, the second semiconductor thin film may be made of Indium Gallium Zinc Oxide (IGZO), wherein an electron mobility of Indium Gallium Zinc Oxide (IGZO) is higher than an electron mobility of amorphous silicon.

In an exemplary implementation mode, after this patterning process, the fanout region 201 of the bonding region may include the first insulation layer 11, the second insulation layer 12, the third insulation layer 13, and the fourth insulation layer 14 stacked on the base substrate 10.

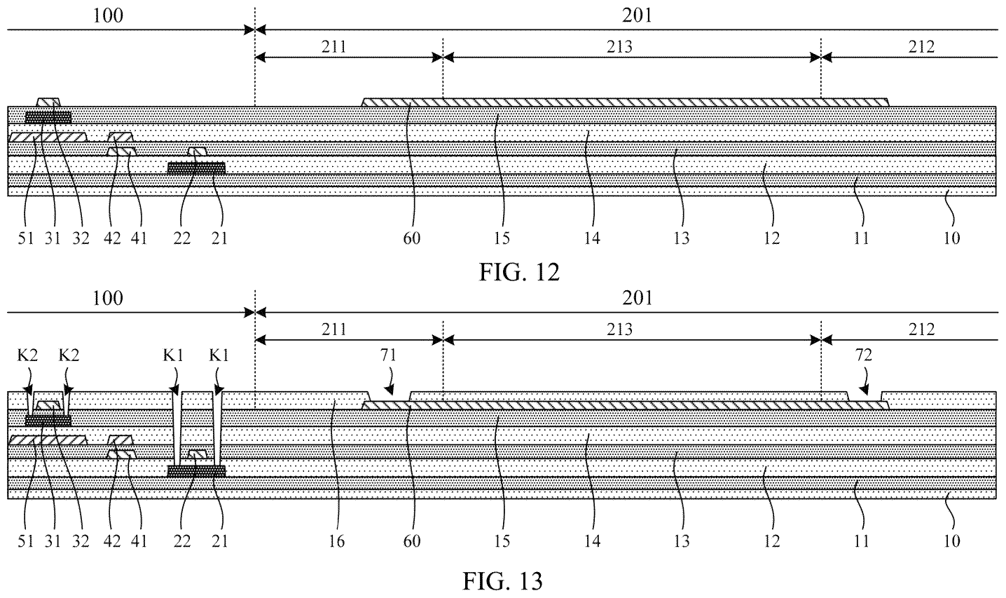

(5) Forming a pattern of a third conductive layer. In an exemplary implementation mode, forming a pattern of a third conductive layer may include: sequentially depositing a fifth insulation thin film and a third conductive thin film on the base substrate where the aforementioned patterns are formed, patterning the third conductive thin film through a patterning process to form a fifth insulation layer 15 covering the pattern of the second semiconductor layer and a pattern of a third conductive layer disposed on the fifth insulation layer 15. The pattern of the third conductive layer may at least include a second gate electrode 32 and a power supply connection line 60, as shown in FIG. 12. In an exemplary implementation mode, the third conductive layer may be referred to as a third gate metal (GATE3) layer.

In an exemplary implementation mode, the second gate electrode 32 may be located in the display region 100, and an orthographic projection of the second gate electrode 32 on the base substrate may be located within a range of an orthographic projection of the second active layer 31 on the base substrate.

In an exemplary implementation mode, the power supply connection line 60 may be located in the fanout region 210 in the bonding region, and the power supply connection line 60 is configured to be connected with a first lap electrode and a second lap electrode which are subsequently formed.

In an exemplary implementation mode, the fanout region 210 in the bonding region may at least include a first transition region 211, an isolation dam region 213, and a second transition region 212 disposed in sequence along a direction away from the display region 100. The first transition region 211 is connected to the display region 100 and is configured as a region where a cathode extends, the isolation dam region 213 is connected to the first transition region 211 and is configured as a region where an isolation dam and a partition slot are disposed, the second transition region 212 is connected to the isolation dam region 213 and is configured as a region outside an encapsulation structure layer. In an exemplary implementation mode, the power supply connection line 60 may be located in a partial region of the first transition region 211 at a side away from the display region, an entire region of the isolation dam region 213, and a partial region of the second transition region 212 at a side close to the display region, i.e., the power supply connection line 60 may extend from the first transition region 211 through the isolation dam region 213 to the second transition region 212, and the power supply connection line 60 is configured as a transfer connection line for a first power supply line to cross the isolation dam region 213.

In an exemplary implementation mode, after this patterning process, the fanout region 201 of the bonding region may include the first insulation layer 11, the second insulation layer 12, the third insulation layer 13, the fourth insulation layer 14, the fifth insulation layer 15, and the power supply connection line 60 stacked on the base substrate 10.

(6) Forming a pattern of a sixth insulation layer. In an exemplary implementation mode, forming a pattern of a sixth insulation layer may include: depositing a sixth insulation thin film on the base substrate where the aforementioned patterns are formed, and patterning the sixth insulation thin film through a patterning process to form the sixth insulation layer 16 covering the pattern of the third conductive layer. A plurality of vias and a plurality of connection openings are disposed on the sixth insulation layer 16, as shown in FIG. 13.

In an exemplary implementation mode, the plurality of vias may be located in the display region 100, and the plurality of vias may at least include first vias K1 respectively located at both ends of the first active layer 21, and second vias K2 respectively located at both ends of the second active layer 31.

In an exemplary implementation mode, an orthographic projection of a first via K1 on the base substrate may be located within a range of an orthographic projection of the first active layer 21 on the base substrate. The sixth insulation layer 16, the fifth insulation layer 15, the fourth insulation layer 14, the third insulation layer 13, and the second insulation layer 12 within the first via K1 are etched away to expose a surface of the first active layer 21, and the first via K1 is configured to such that a first source electrode and a first drain electrode which are formed subsequently are connected with the first active layer 21, respectively, through the via. An orthographic projection of a second via K2 on the base substrate may be located within a range of an orthographic projection of the second active layer 31 on the base substrate. The sixth insulation layer 16 and the fifth insulation layer 15 within the second via K2 are etched away to expose a surface of the second active layer 31, and the second via K2 is configured such that a second source electrode and a second drain electrode which are formed subsequently are connected with the second active layer 31, respectively, through the via.

In an exemplary implementation mode, the plurality of connection openings may be located in the fanout region 201, and the plurality of connection openings may at least include a first connection opening 71 located in the first transition region 211 and a second connection opening 72 located in the second transition region 212. The sixth insulation layer 16 within the first connection opening 71 is etched away to expose a surface of the power supply connection line 60 at a side close to the display region, and the sixth insulation layer 16 within the second connection opening 72 is etched away to expose a surface of the power supply connection line 60 at a side away from the display region. In an exemplary implementation mode, the first connection opening 71 and the second connection opening 72 are configured such that a lap electrode formed subsequently is connected with the power supply connection line 60 through the connection openings.

In an exemplary implementation mode, after this patterning process, the fanout region 201 of the bonding region may include the first insulation layer 11, the second insulation layer 12, the third insulation layer 13, the fourth insulation layer 14, the fifth insulation layer 15, the power supply connection line 60, and the sixth insulation layer 16 stacked on the base substrate 10.

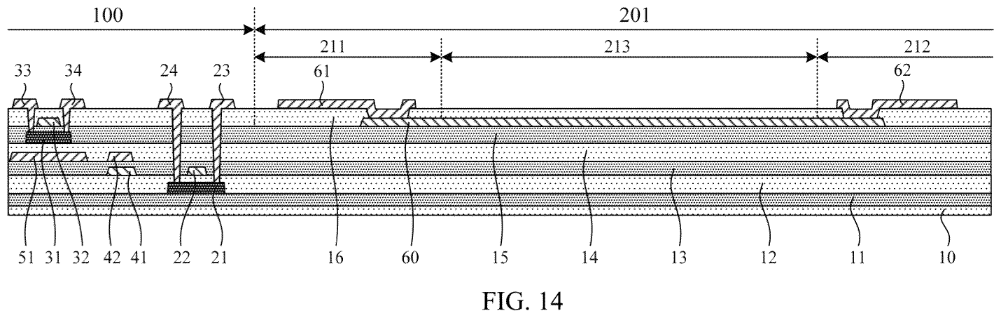

(7) Forming a pattern of a fourth conductive layer. In an exemplary implementation mode, forming a pattern of a fourth conductive layer may include: depositing a fourth conductive thin film on the base substrate where the aforementioned patterns are formed, and patterning the fourth conductive thin film through a patterning process to form a pattern of a fourth conductive layer on the sixth insulation layer 16, wherein the fourth conductive layer pattern may at least include a first source electrode 23, a first drain electrode 24, a second source electrode 33, a second drain electrode 34, a first lap electrode 61, and a second lap electrode 62, as shown in FIG. 14. In an exemplary implementation mode, the third conductive layer may be referred to as a first source-drain metal (SD1) layer.

In an exemplary implementation mode, the first source electrode 23, the first drain electrode 24, the second source electrode 33, and the second drain electrode 34 may be located in the display region 100. The first source electrode 23 and the first drain electrode 24 are respectively connected with the first active layer 21 through the first vias K1, and the second source electrode 33 and the second drain electrode 34 are respectively connected with the second active layer 31 through the second vias K2.

In an exemplary implementation mode, the first lap electrode 61 and the second lap electrode 62 may be located in the fanout region 201. The first lap electrode 61 may be located in the first transition region 211 of the fanout region 201 and the first lap electrode 61 is connected with a side of the power supply connection line 60 close to the display region through the first connection opening 71. The second lap electrode 62 may be located in the second transition region 212 of the fanout region 201 and the second lap electrode 62 is connected with a side of the power supply connection line 60 away from the display region through the second connection opening 72.

In an exemplary implementation mode, the first active layer 21, the first gate electrode 22, the first source electrode 23, and the first drain electrode 24 constitute a first transistor 20 which is a low temperature poly silicon thin film transistor. The second active layer 31, the second gate electrode 32, the second source electrode 33, and the second drain electrode 34 constitute a second transistor 30 which is an oxide thin film transistor. The first electrode plate 41 and the second electrode plate 42 constitute a storage capacitor 40. In an exemplary implementation mode, the first transistor 20 may be a drive transistor in a pixel drive circuit, and the second transistor 30 may be a switching transistor in the pixel drive circuit.

In an exemplary implementation mode, after this patterning process, the fanout region 201 of the bonding region may include the first insulation layer 11, the second insulation layer 12, the third insulation layer 13, the fourth insulation layer 14, the fifth insulation layer 15, the power supply connection line 60, the sixth insulation layer 16, and the first source-drain metal layer stacked on the base substrate 10, and the first source-drain metal layer may include the first lap electrode 61 and the second lap electrode 62.

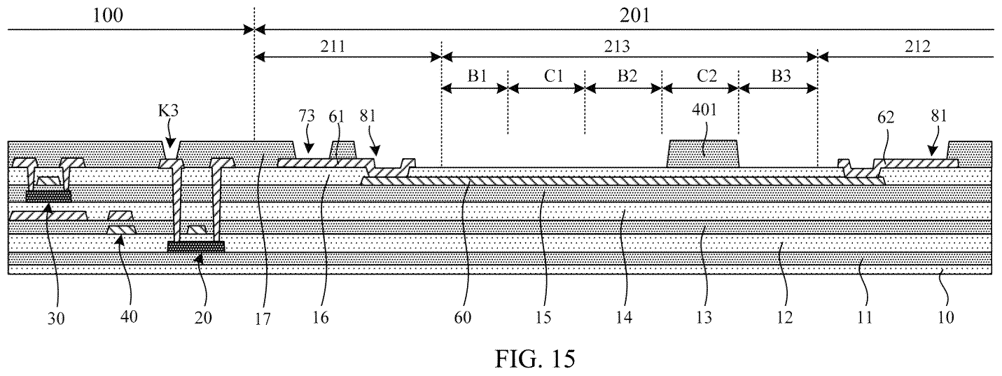

(8) Forming a pattern of a first planarization layer. In an exemplary implementation mode, forming a pattern of a first planarization layer may include: coating a first planarization thin film on the base substrate where the aforementioned patterns are formed, and patterning the first planarization thin film through a patterning process to form a pattern of a first Planarization (PLN) layer 17 covering the fourth conductive layer, as shown in FIG. 15.

In an exemplary implementation mode, the pattern of the first planarization layer 17 may at least include a third via K3, a third connection opening 73, a first partition slot 81, and a first dam foundation 401.

In an exemplary implementation mode, the third via K3 may be located in the display region 100, the first planarization layer 17 within the third via K3 is removed to expose a surface of a first drain electrode of the first transistor 20, and the third via K3 is configured such that an anode connection electrode formed subsequently is connected with the first drain electrode through the via.

In an exemplary implementation mode, the first partition slot 81 may be located in the fanout region 201, an orthographic projection of the first partition slot 81 on the base substrate may contain an orthographic projection of the isolation dam region 213 on the base substrate, and the first planarization thin film within the first partition slot 81 is removed to expose surfaces of the sixth insulation layer 16, the first lap electrode 61, and the second lap electrode 62, respectively.

In an exemplary implementation mode, the first planarization layer 17 at a side of the first partition slot 81 close to the display region 100 covers a partial region of and an edge of the first lap electrode 61 at a side close to the display region 100, and the first partition slot 81 exposes a surface of a region of the first lap electrode 61 at a side away from the display region 100.

In an exemplary implementation mode, the first planarization layer 17 at a side of the first partition slot 81 away from the display region 100 covers a partial region of and an edge of the second lap electrode 62 at a side away from the display region 100, and the first partition slot 81 exposes a surface of a region of the second lap electrode 62 at a side close to the display region 100.

In an exemplary implementation mode, the third connection opening 73 may be located on the first planarization layer 17 covering the first lap electrode 61, the first planarization thin film within the third connection opening 73 is removed to expose a surface of the first lap electrode 61, the third connection opening 73 is configured such that a first power supply line subsequently formed is connected with the first lap electrode 61 through the third connection opening 73.

In an exemplary implementation mode, the first dam foundation 401 may be located in a region where the first partition slot 81 is located. The isolation dam region 213 may at least include a first slot region B1, a first dam region C1, a second slot region B2, a second dam region C2, and a third slot region B3 disposed in sequence along a direction away from the display region 100. The first dam foundation 401 may be located in the second dam region C2, the first dam foundation 401 is disposed at a side of the sixth insulation layer 16 away from the base substrate, and the first dam foundation 401 is configured as one dam foundation of a second isolation dam.

In an exemplary implementation mode, in addition to the first dam foundation 401, a surface of the sixth insulation layer 16 is exposed in another region within the first partition slot 81.

After this patterning process, the fanout region 201 of the bonding region may include the first insulation layer 11, the second insulation layer 12, the third insulation layer 13, the fourth insulation layer 14, the fifth insulation layer 15, the power supply connection line 60, the sixth insulation layer 16, the first source-drain metal layer, and the first planarization layer 17 which are stacked on the base substrate 10. The first source-drain metal layer may include the first lap electrode 61 and the second lap electrode 62. The first planarization layer 17 is formed with the first partition slot 81, the first partition slot 81 exposes the surface of the sixth insulation layer 16, and the first dam foundation 401 is formed within the first partition slot 81.

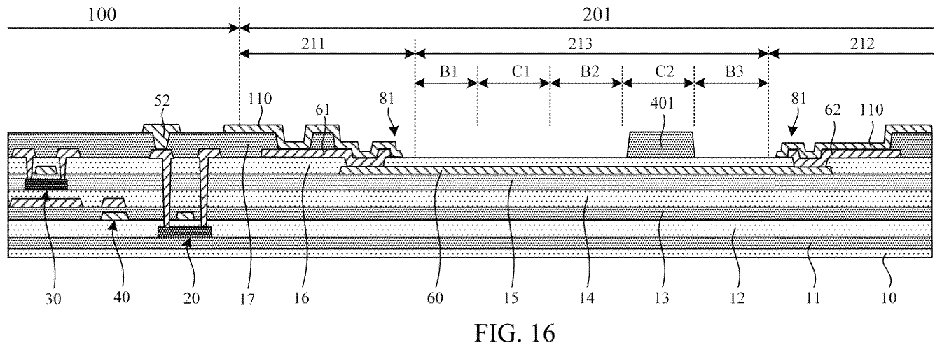

(9) Forming a pattern of a fifth conductive layer. In an exemplary implementation mode, forming a pattern of a fifth conductive layer may include: depositing a fifth conductive thin film on the base substrate where the aforementioned patterns are formed, and patterning the fifth conductive thin film through a patterning process to form a pattern of a fifth conductive layer on the first planarization layer 17. The pattern of the fifth conductive layer may at least include an anode connection electrode 52 and a first power supply line 110, as shown in FIG. 16. In an exemplary implementation mode, the fifth conductive layer may be referred to as a second source-drain metal (SD2) layer.

In an exemplary implementation mode, the anode connection electrode 52 may be located in the display region 100, the anode connection electrode 52 is connected with the first drain electrode of the first transistor 20 through the third via K3, and the anode connection electrode 52 is configured to be connected with an anode subsequently formed.

In an exemplary implementation mode, the first power supply line 110 may be located in the display region 100 and the first transition region 211 and the second transition region 212 of the fanout region 201, respectively. The first power supply line 110 located in the display region 100 is connected with a first power supply line of the pixel drive circuit, the first power supply line 110 located in the first transition region 211 of the fanout region 201 is connected with the first lap electrode 61, and the first power supply line 110 located in the second transition region 212 of the fanout region 201 is connected with the second lap electrode 62.

In an exemplary implementation mode, in the first transition region 211 of the fanout region 201, the first power supply line 110 is connected with the first lap electrode 61 through the third connection opening 73 on one hand, and extends along a direction away from the display region 100 on the other hand to be lapped with the first lap electrode 61 exposed in the first partition slot 81, and the first power supply line 110 covers an edge of the first lap electrode 61 at a side away from the display region 100.

In an exemplary implementation mode, in the second transition region 212 of the fanout region 201, the first power supply line 110 is lapped with the second lap electrode 62 exposed in the first partition slot 81, and the first power supply line 110 covers an edge of the second lap electrode 62 at a side close to the display region 100.

In an exemplary implementation mode, in the present disclosure, the first power supply line 110 covers the edge of the first lap electrode 61 at a side away from the display region 100 and the edge of the second lap electrode 62 at a side close to the display region 100, so that not only the first lap electrode 61 and the second lap electrode 62 may be effectively protected, but also an anti-peeling capability of a film layer may be enhanced, and product quality may be improved. In the present disclosure, the first power supply line 110 is connected with the first lap electrode 61 through the third connection opening 73 and the first partition slot 81, respectively, so that not only connection reliability may be improved, but also process quality of preparing the first planarization layer may be improved by using the third connection opening 73 as a gas relief port.

In an exemplary implementation mode, since the first power supply line 110 of the fanout region 201 is connected with the first lap electrode 61 and the second lap electrode 62, respectively, and the first lap electrode 61 and the second lap electrode 62 are respectively connected with the power supply connection line 60, it is achieved that the first power supply line 110 of the first transition region 211 and the first power supply line 110 of the second transition region 212 are interconnected through the first lap electrode 61, the power supply connection line 60, and the second lap electrode 62.

In an exemplary implementation mode, in the first transition region 211, the first power supply line 110 located in the SD2 layer is transferred to the power supply connection line 60 located in the GATE3 layer through the first lap electrode 61 located in the SD1 layer. After the power supply connection line 60 located in the GATE3 layer crosses the isolation dam region 213 and enters the second transition region 212, the power supply connection line 60 is transferred to the first power supply line 110 located in the SD2 layer through the second lap electrode 62 located in the SD1 layer to form the first power supply line 110 crossing the isolation dam region 213 through a transfer structure.

After this patterning process, the fanout region 201 of the bonding region may include the first insulation layer 11, the second insulation layer 12, the third insulation layer 13, the fourth insulation layer 14, the fifth insulation layer 15, the power supply connection line 60, the sixth insulation layer 16, the first source-drain metal layer, the first planarization layer 17, and the second source-drain metal layer stacked on the base substrate 10. The first source-drain metal layer may include the first lap electrode 61 and the second lap electrode 62, the second source-drain metal layer may include the first power supply line 110, and the first power supply line 110 crosses the isolation dam region 213 using the first lap electrode 61, the power supply connection line 60, and the second lap electrode 62.

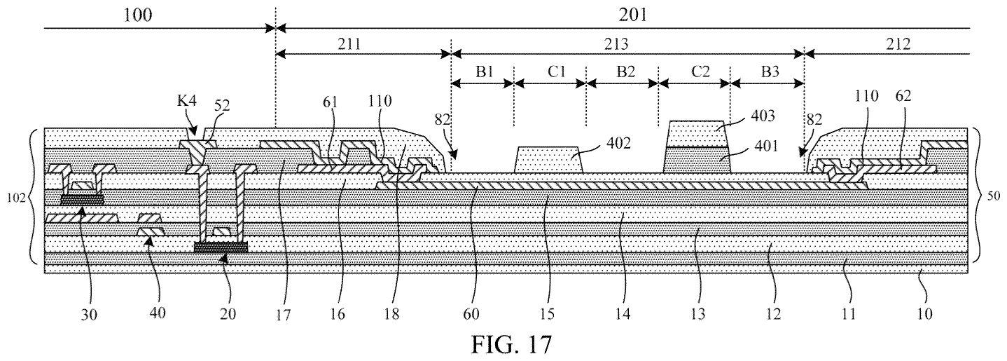

(10) Forming a pattern of a second planarization layer. In an exemplary implementation mode, forming a pattern of a second planarization layer may include: coating a second planarization thin film on the base substrate where the aforementioned patterns are formed, and patterning the second planarization thin film through a patterning process to form a pattern of a second planarization layer 18 covering the fifth conductive layer, as shown in FIG. 17.

In an exemplary implementation mode, the pattern of the second planarization layer 18 may at least include a fourth via K4, a second partition slot 82, a second dam foundation 402, and a third dam foundation 403.

In an exemplary implementation mode, the fourth via K4 may be located in the display region 100, the second planarization layer 18 within the fourth via K4 is removed to expose a surface of the anode connection electrode 52, and the fourth via K4 is configured such that an anode subsequently formed is connected with the anode connection electrode 52 through the via.

In an exemplary implementation mode, the second partition slot 82 may be located in the fanout region 201, an orthographic projection of the second partition slot 82 on the base substrate may contain an orthographic projection of the isolation dam region 213 on the base substrate, the orthographic projection of the second partition slot 82 on the base substrate may contain an orthographic projection of the first partition slot 81 on the base substrate, the second planarization thin film within the second partition slot 82 is removed to expose the sixth insulation layer 16 of the isolation dam region 213.

In an exemplary implementation mode, the second planarization layer 18 at a side of the second partition slot 82 close to the display region 100 covers an edge of the first power supply line 100 located in the first transition region 211 away from the display region 100, and the second planarization layer 18 at a side of the second partition slot 82 away from the display region 100 covers an edge of the first power supply line 100 located in the second transition region 212 close to the display region 100, thus achieving covering the edge of the first power supply line 100 by the second planarization layer 18, which may enhance an anti-peeling capability of a film layer and improve product quality.

In an exemplary implementation mode, the second dam foundation 402 and the third dam foundation 403 may be located in a region where the second partition slot 82 is located. The second dam foundation 402 may be located in the first dam region C1, the second dam foundation 402 may be disposed at a side of the sixth insulation layer 16 away from the base substrate, and the second dam foundation 402 is configured as one dam foundation of a first isolation dam. The third dam foundation 403 may be located in the second dam region C2, the third dam foundation 403 may be disposed at a side of the first dam foundation 401 away from the base substrate, and the third dam foundation 403 is configured as another dam foundation of a second isolation dam.

After this patterning process, the fanout region 201 of the bonding region may include the first insulation layer 11, the second insulation layer 12, the third insulation layer 13, the fourth insulation layer 14, the fifth insulation layer 15, the power supply connection line 60, the sixth insulation layer 16, the first source-drain metal layer, the first planarization layer 17, the second source-drain metal layer, and the second planarization layer 18 which are stacked on the base substrate 10. The first source-drain metal layer may include the first lap electrode 61 and the second lap electrode 62. The second source-drain metal layer may include the first power supply line 110, the first power supply line 110 crosses the isolation dam region 213 using the first lap electrode 61, the power supply connection line 60, and the second lap electrode 62. The second planarization layer 18 is formed with the second partition slot 82, and the second partition slot 82 exposes the surface of the sixth insulation layer 16. The second partition slot 82 is formed with the first dam foundation 401, the second dam foundation 402, and the third dam foundation 403.

Therefore, preparation of patterns of a drive structure layer 102 of the display region 100 and a bonding structure layer 50 of the fanout region 201 on the base substrate 10 is completed. The drive structure layer 102 of the display region 100 may at least include the first transistor 20, the second transistor 30, and the storage capacitor 40 constituting the pixel drive circuit. The bonding structure layer 50 of the fanout region 201 may at least include the first insulation layer 11 to the fifth insulation layer 15 disposed on the base substrate 10; the power supply connection line 60 disposed at a side of the fifth insulation layer 15 away from the base substrate; the sixth insulation layer 16 disposed at a side of the power supply connection line 60 away from the base substrate; the first lap electrode 61 and the second lap electrode 62, which are respectively connected with the power supply connection line 60, disposed at a side of the sixth insulation layer 16 away from the base substrate; the first planarization layer 17 disposed at a side of the first lap electrode 61 and the second lap electrode 62 away from the base substrate; the first power supply line 110, which is respectively connected with the first lap electrode 61 and the second lap electrode 62, disposed at a side of the first planarization layer 17 away from the base substrate; the second planarization layer 18 disposed at a side of the first power supply line 110 away from the base substrate, wherein the second partition slot 82 is formed on the second planarization layer 18, and the second partition slot 82 exposes the surface of the sixth insulation layer 16.

In an exemplary implementation mode, the base substrate may be a rigid base substrate or may be a flexible base substrate. A multi-layer structure may be adopted for the flexible base substrate. For example, the base substrate may include a first flexible material layer, a first inorganic material layer, a semiconductor layer, a second flexible material layer, and a second inorganic material layer which are stacked. Materials of the first flexible material layer and the second flexible material layer may be Polyimide (P1), Polyethylene Terephthalate (PET), or a surface-treated polymer soft film, etc., and materials of the first inorganic material layer and the second inorganic material layer may be Silicon Nitride (SiNx) or Silicon Oxide (SiOx), etc. to improve an anti-water-oxygen capability of the base substrate. The first inorganic material layer and the second inorganic material layer may also be called barrier layers, and amorphous silicon (a-si) may be adopted for a material of the semiconductor layer.

In an exemplary implementation mode, the first insulation layer, the second insulation layer, the third insulation layer, the fourth insulation layer, the fifth insulation layer, and the sixth insulation layer may be made of any one or more of Silicon Oxide (SiOx), Silicon Nitride (SiNx), and Silicon Oxynitride (SiON), and may be a single layer, a multi-layer, or a composite layer. The first insulation layer may be referred to as a buffer layer, the second insulation layer, the third insulation layer, the fourth insulation layer, and the fifth insulation layer may be referred to as Gate Insulation (GI) layers, and the sixth insulation layer may be referred to as an Interlayer Dielectric (ILD) layer. The first conductive layer, the second conductive layer, the third conductive layer, the fourth conductive layer, and the fifth conductive layer may be made of a metal material, such as any one or more of Argentum (Ag), Copper (Cu), Aluminum (Al), Titanium (Ti), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Ti/Al/Ti. The first planarization layer and the second planarization layer may be made of an organic material, such as resin or polyimide.

In an exemplary implementation mode, the third conductive layer may be made of metallic Molybdenum (Mo) or an alloy material of molybdenum, and has characteristics such as not reacting with a wet etching solution.

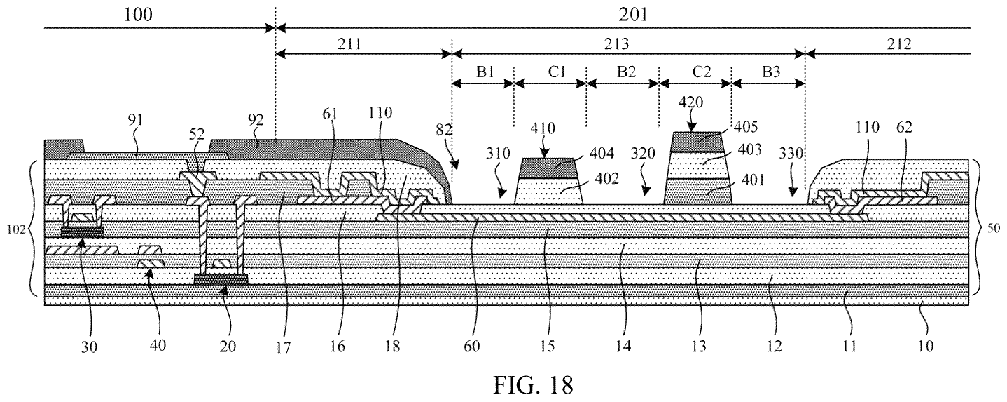

(11) Forming patterns of an anode conductive layer and a pixel definition layer. In an exemplary implementation mode, forming patterns of an anode conductive layer and a pixel definition layer may include: first depositing a transparent conductive thin film on the base substrate where the aforementioned patterns are formed, patterning the transparent conductive thin film through a patterning process to form a pattern of an anode 91 on the second planarization layer 18, then coating a pixel definition thin film, and patterning the pixel definition thin film through a patterning process to form a pixel definition layer 92, a fourth dam foundation 404, a fifth dam foundation 405, a first isolation slot 310, a second isolation slot 320, and a third isolation slot 330, as shown in FIG. 18.

In an exemplary implementation mode, the anode 91 may be located in the display region 100 and the anode 91 is connected with the anode connection electrode 52 through the fourth via K4. Since the anode connection electrode 52 is connected with the first drain electrode of the first transistor 20 through a via, a connection between the anode 91 and the pixel drive circuit is achieved.

In an exemplary implementation mode, the pixel definition layer 92 may be located in the display region 100 and the first transition region 211 of the fanout region 201. The pixel definition layer 92 of the display region 100 is provided with a pixel opening, and the pixel definition layer 92 within the pixel opening is removed to expose a surface of the anode 91. The pixel definition layer 92 of the first transition region 211 extends to the second partition slot 82 and covers a sidewall of the second partition slot 82 at a side close to the display region.

In an exemplary implementation mode, the fourth dam foundation 404 and the fifth dam foundation 405 may be located in a region where the second partition slot 82 is located. The fourth dam foundation 404 may be located in the first dam region C1 and may be disposed at a side of the second dam foundation 402 away from the foundation, the fourth dam foundation 404 is configured as the other dam foundation of the first isolation dam, and the second dam foundation 402 and the fourth dam foundation 404 constitute the first isolation dam 410. The fifth dam foundation 405 may be located in the second dam region C2 and may be disposed at a side of the third dam foundation 403 away from the base substrate, the fifth dam foundation 405 is configured as another dam foundation of the second isolation dam, and the first dam foundation 401, the third dam foundation 403, and the fifth dam foundation 405 constitute the second isolation dam 420. In an exemplary implementation mode, a distance between the first isolation dam 410 and the display region 100 is less than a distance between the second isolation dam 420 and the display region 100, and a distance between a surface of the first isolation dam 410 away from the base substrate and the base substrate is less than a distance between a surface of the second isolation dam 420 away from the base substrate and the base substrate.

In an exemplary implementation mode, the first isolation slot 310 may be located in the first slot region B1, i.e., located between the first isolation dam 410 and the first transition region 211, and the first planarization layer, the second planarization layer, and the pixel definition layer within the first isolation slot 310 are removed to expose the sixth insulation layer 16.

In an exemplary implementation mode, the second isolation slot 320 may be located in the second slot region B2, i.e., located between the first isolation dam 410 and the second isolation dam 420, and the first planarization layer, the second planarization layer, and the pixel definition layer within the second isolation slot 320 are removed to expose the sixth insulation layer 16.

In an exemplary implementation mode, the third isolation slot 330 may be located in the third slot region B3, i.e., located between the second isolation dam 420 and the second transition region 212, and the first planarization layer, the second planarization layer, and the pixel definition layer within the third isolation slot 330 are removed to expose the sixth insulation layer 16.

In exemplary embodiments, the transparent conductive layer may be of a single-layer structure or a multi-layer composite structure, Indium Tin Oxide (ITO) or Indium Zinc Oxide (IZO) may be adopted for the single-layer structure, and ITO/Al/ITO or the like may be adopted for the multi-layer composite structure. The pixel definition layer may be made of polyimide, acrylic, polyethylene terephthalate, or the like.

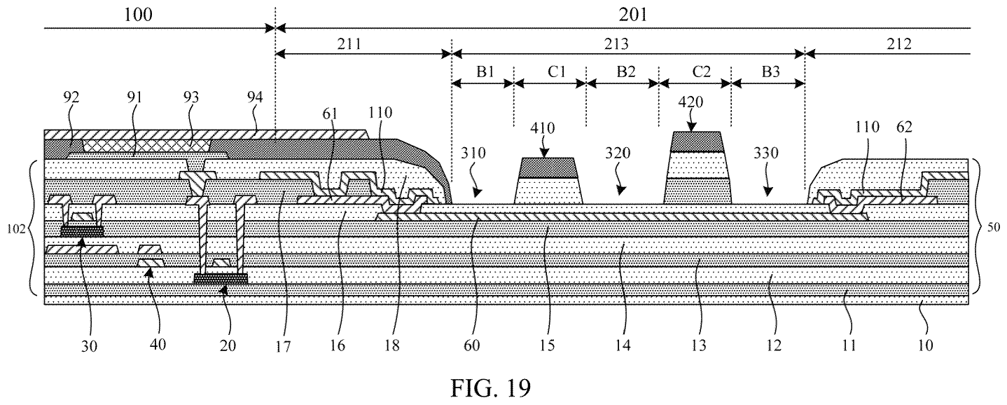

(12) Forming patterns of an organic emitting layer and a cathode. In an exemplary implementation mode, forming patterns of an organic emitting layer and a cathode may include: first forming an organic emitting layer 93 by means of evaporation or inkjet printing on the base substrate where the aforementioned patterns are formed, and then forming a cathode 94 by evaporation using an open mask, as shown in FIG. 19.

In an exemplary implementation mode, the organic emitting layer 93 may be formed within the pixel opening provided by the pixel definition layer 92, so as to achieve a connection between the organic emitting layer 93 and the anode 91.

In an exemplary implementation mode, the organic emitting layer 93 may include an Emitting Layer (EML) and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary implementation mode, one or more layers of hole injection layers, hole transport layers, electron block layers, hole block layers, electron transport layers, and electron injection layers of all light emitting units may be respectively connected together to be a common layer. Emitting layers of adjacent sub-pixels may be overlapped slightly, or may be mutually isolated.

In an exemplary implementation mode, the cathode 94 may be located in the display region 100 and the first transition region 211 of the fanout region 201, and the cathode 94 in the display region 100 is lapped with the organic emitting layer 93, and a distance between an edge of the cathode 94 in the first transition region 211 at a side away from the display region 100 and an edge of the display region is less than a distance between the first isolation slot 310 and the edge of the display region, i.e., a width of the cathode 94 within the fanout region 201 is less than a width of the first transition region 211.

In an exemplary implementation mode, the cathode may be made of any one or more of Magnesium (Mg), Argentum (Ag), Aluminum (Al), Copper (Cu), and Lithium (Li), or an alloy made of any one or more of the above metals.

(14) Forming a pattern of an encapsulation structure layer. In an exemplary implementation mode, forming a pattern of an encapsulation structure layer may include: first forming a first encapsulation layer 95 by means of deposition on the base substrate where the aforementioned patterns are formed, then forming a second encapsulation layer 96 by means of inkjet printing, then forming a third encapsulation layer 97 by means of deposition, and forming a laminated structure of the first encapsulation layer 95, the second encapsulation layer 96, and the third encapsulation layer 97, as shown in FIG. 7.

In an exemplary implementation mode, the first encapsulation layer 95 may be made of an inorganic material, covering the cathode 94 in the display region 100, covering the first isolation slot 310, the second isolation slot 320, and the third isolation slot 330 in the fanout region 201, respectively, and wrapping the first isolation dam 410 and the second isolation dam 420, respectively. The second encapsulation layer 96 may be made of an organic material and is disposed in the display region 100 and in a region in the fanout region 201 where the first isolation dam 410 is close to the display region. The third encapsulation layer 97 may be made of an inorganic material and covers the first encapsulation layer 95 and the second encapsulation layer 96.

In an exemplary implementation mode, since the sixth insulation layer of the inorganic material is exposed by a plurality of isolation slots, the first encapsulation layer of the inorganic material directly covers the sixth insulation layer, which not only improves an anti-peeling capability of a film layer, but also effectively blocks a propagation path of water vapor, which may ensure that the external water vapor cannot enter the display region and improve an encapsulation effect to a maximum extent.

In a display substrate, for a first power supply line located in an SD2 layer in a bonding region, an integrated structure directly crossing a fanout region is adopted, and a plurality of partition slots expose a surface of the first power supply line since a first planarization layer, a second planarization layer, and a pixel definition layer (an organic material layer) in the plurality of partition slots are removed. Although a distance between an edge of a cathode and a partition slot is set in a design, when a process margin at a cathode opening edge is insufficient or a process parameter fluctuates greatly, the cathode will extend to a region where the partition slot is located, which will lead to lap between the cathode and the first power supply line and cause a short circuit of the cathode.

In the display substrate provided by the exemplary embodiment of the present disclosure, the first power supply line in the bonding region is set as a transfer structure, and the first power supply line located in the SD2 layer crosses a plurality of partition slots through the power supply connection line located in the GATE3 layer, so that neither the first power supply line nor the power supply connection line is exposed by the plurality of partition slots, but an inorganic insulation layer covering the power supply connection line is exposed. Even if the cathode extends to a region where a partition slot is located, the cathode will not be connected with the first power supply line or the power supply connection line, which not only effectively avoids a short-circuit situation of the cathode, effectively avoids poor display of the display substrate, but also increases a process margin and improves production quality and a production efficiency.

In the transfer structure provided by the exemplary embodiment of the present disclosure, the first power supply line located in the SD2 layer is respectively connected with the first lap electrode and the second lap electrode located in the SD1 layer, and the first lap electrode and the second lap electrode located in the SD1 layer are respectively connected with the power supply connection line located in the GATE3 layer, thus it is achieved that the first power supply line in the first transition region is interconnected with the first power supply line in the second transition region through the first lap electrode, the power supply connection line, and the second lap electrode, and the transfer structure is simple and a connection is reliable, thus improving process quality.

In the exemplary embodiment of the present disclosure, the first power supply line is used for covering edges of the first lap electrode and the second lap electrode, the second planarization layer is used for covering an edge of the first power supply line, and the pixel definition layer is used for covering an edge of the second planarization layer, thereby effectively enhancing an anti-peeling capability of a film layer and improving product quality.

In the exemplary embodiment of the present disclosure, by providing a plurality of partition slots in an isolation dam region, an organic material layer within a partition slot is removed, an intrusion path of water vapor along the organic material layer to a display region is cut off, a risk of encapsulation failure is reduced, poor display of the display substrate is avoided, and display quality is improved.

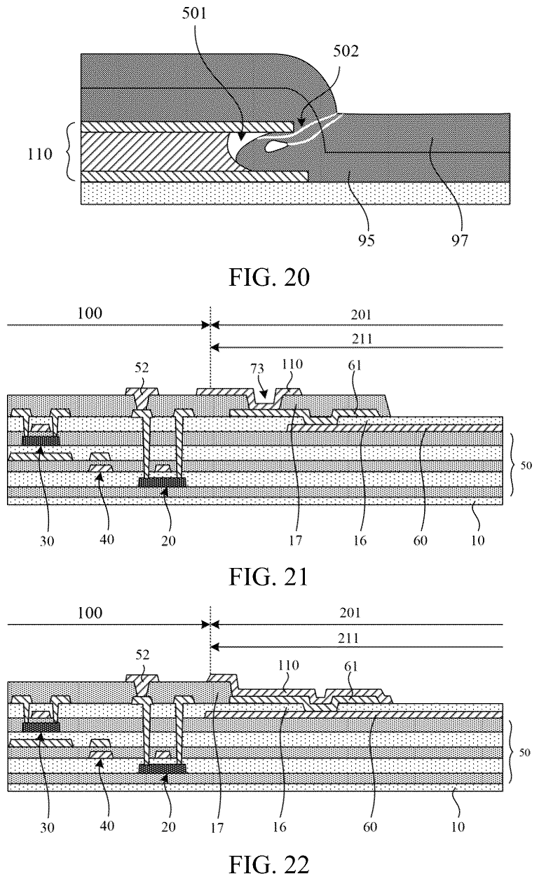

FIG. 20 is a schematic diagram showing that a GDS defect occurs on a display substrate. In a display substrate, an edge of a first power supply line 110 within a plurality of partition slots is exposed since an organic material layer within the plurality of partition slots is removed. For the first power supply line 110 with a Ti/Al/Ti multi-layer composite structure, the edge of the first power supply line 110 will be eroded by an anode etching solution in a subsequent process of etching an anode. Since an etching rate of etching Al by the etching solution is greater than that of etching Ti, a side pit will be formed at the edge of the eroded first power supply line 110, and a Ti layer above an Al layer protrudes from the Al layer for a certain distance, forming an “eave” structure, as shown in FIG. 20. In a subsequent process of forming the first encapsulation layer 95 and the third encapsulation layer 97 using Chemical Vapor Deposition (CVD), the “eave” structure blocks vapor deposited particles, so that the side pit cannot be filled with an encapsulation material, thereby forming a cavity 501. In this way, when a crack 502 appears in the first encapsulation layer 95 and the third encapsulation layer 97, external water vapor may enter the cavity 501 through the crack 502, causing water vapor to circulate at the edge of the first power supply line 110 until it diffuses to the display region, resulting in a GDS defect in the display region due to water and oxygen erosion.

In the display substrate provided by the exemplary embodiment of the present disclosure, the first power supply line of the bonding region is set as a transfer structure, the first power supply line located in the SD2 layer crosses the isolation dam region through the power supply connection line located in the GATE3 layer, and the power supply connection line is covered with an inorganic insulation layer, so that an edge of the first power supply line and an edge of the power supply connection line will not be exposed within a partition slot, and the edge of the first power supply line and the edge of the power supply connection line will not be eroded by an anode etching solution and there will be no cavity, which can ensure better appearance of the first encapsulation layer and the third encapsulation layer, effectively avoid the GDS defect, effectively avoid poor display of the display substrate, and improve a yield and product reliability.

In an exemplary implementation mode, the GATE3 layer may be made of metallic molybdenum (Mo) or an alloy material of molybdenum, so that the power supply connection line reacts with the anode etching solution, which may further avoid the GDS defect and increase a process margin.

In the present disclosure, a GATE3 layer existing in an LTPO display substrate is used as a transfer structure, so that a preparation process may be achieved by utilizing an existing mature preparation device, has little improvement on an existing process, may be well compatible with an existing preparation process, and has simple process realization, easy implementation, a high production efficiency, a low production cost, and a high yield. Since a structure and a process route of a power supply line passing through an isolation dam are relatively common, there is a great possibility that the display substrate will have short-circuit of a cathode and a GDS defect, so a solution of the present disclosure has a wide application prospect and may be applied to a display substrate with any number of partition slots.

The description of the structure and preparation process of the display substrate according to the present disclosure is merely illustrative. In an exemplary implementation mode, a corresponding structure may be changed and patterning processes may be increased or decreased according to actual needs. For example, a transfer structure is adopted for the second power supply line of the bonding region, and the second power supply line located in the SD2 layer crosses the isolation dam region through the power supply connection line located in the GATE3 layer. For another example, a quantity of partition slots of the isolation dam region may be one, two, or more. For another example, the display substrate may be of a double source-drain conductive layer (2SD) structure or a single source-drain conductive layer (1SD) structure. For the single source-drain conductive layer structure, the first power supply line and the second power supply line may be disposed in the SD1 layer, the power supply connection line may be disposed in the GATE3 layer, the first power supply line of the first transition region and the first power supply line of the second transition region are interconnected through the first power supply connection line, and the second power supply line of the first transition region and the second power supply line of the second transition region are interconnected through the second power supply connection line. For another example, in the first transition region, the first power supply line is disposed in the SD2 layer, in the second transition region, the first power supply line is disposed in the SD1 layer, and the second transition region is not provided with the SD2 layer, etc., the present disclosure is not limited thereto.

FIG. 21 is a schematic diagram of a structure of another display substrate according to an exemplary embodiment of the present disclosure, wherein a cross-sectional structure of a first transition region is illustrated. A main body structure of the display substrate of the embodiment is basically the same as that of the display substrate shown in FIG. 7, except that the first power supply line 110 located in the SD2 layer in the first transition region 211 is connected with the first lap electrode 61 only through the third connection opening 73, the first power supply line 110 does not extend in the direction away from the display region, the first power supply line 110 and the first lap electrode 61 are communicated at one side, and an edge of the first lap electrode 61 at a side away from the display region is covered by the first planarization layer 17.

In an exemplary implementation mode, a connection structure of the first lap electrode of the first transition region and the power supply connection line, a connection structure of the first power supply line and the second lap electrode of the second transition region, a connection structure of the second lap electrode and the power supply connection line of the second transition region may be basically the same as those of the foregoing embodiments, so that the first power supply line of the SD2 layer is transferred to the GATE3 layer through the SD1 layer, and the GATE3 layer is transferred back to the SD2 layer through the SD1 layer after crossing a plurality of isolation slots.

According to the display substrate of the exemplary embodiment of the present disclosure, not only a short circuit situation may be effectively avoided and poor display of the display substrate may be effectively avoided, but also a connection structure of the first power supply line and the first lap electrode in the first transition region may be simplified, and process quality may be improved.

FIG. 22 is a schematic diagram of a structure of yet another display substrate according to an exemplary embodiment of the present disclosure, wherein a cross-sectional structure of a first transition region is illustrated. A main body structure of the display substrate of the exemplary embodiment is basically the same as that of the display substrate shown in FIG. 7, except that the first power supply line 110 located in the SD2 layer in the first transition region 211 extends along a direction away from the display region 100, and is lapped with the exposed first lap electrode 61 in the first partition slot, and the first power supply line 110 wraps an edge of the first lap electrode 61 at a side away from the display region 100.

In an exemplary implementation mode, since the third connection opening for connecting the first power supply line 110 with the first lap electrode 61 is not disposed on the first planarization layer 17, the first planarization layer 17 within the first transition region 211 is removed as much as possible (i.e., a region of the first partition slot is enlarged), and water vapor storage of an organic material may be reduced, further avoiding a GDS defect.

In an exemplary implementation mode, a surface of the first lap electrode 61 exposed by removing the first planarization layer 17 is protected by the first power supply line 110 lapped on the surface of the first lap electrode 61.

In an exemplary implementation mode, for a connection structure of the first power supply line and the second lap electrode of the second transition region, a structure in which the first planarization layer is removed as much as possible may be adopted.

According to the display substrate of the exemplary embodiment of the present disclosure, not only a short circuit situation may be effectively avoided and poor display of the display substrate may be effectively avoided, but also water vapor storage of an organic material may be reduced by removing the first planarization layer as much as possible, and a GDS defect may be further avoided.

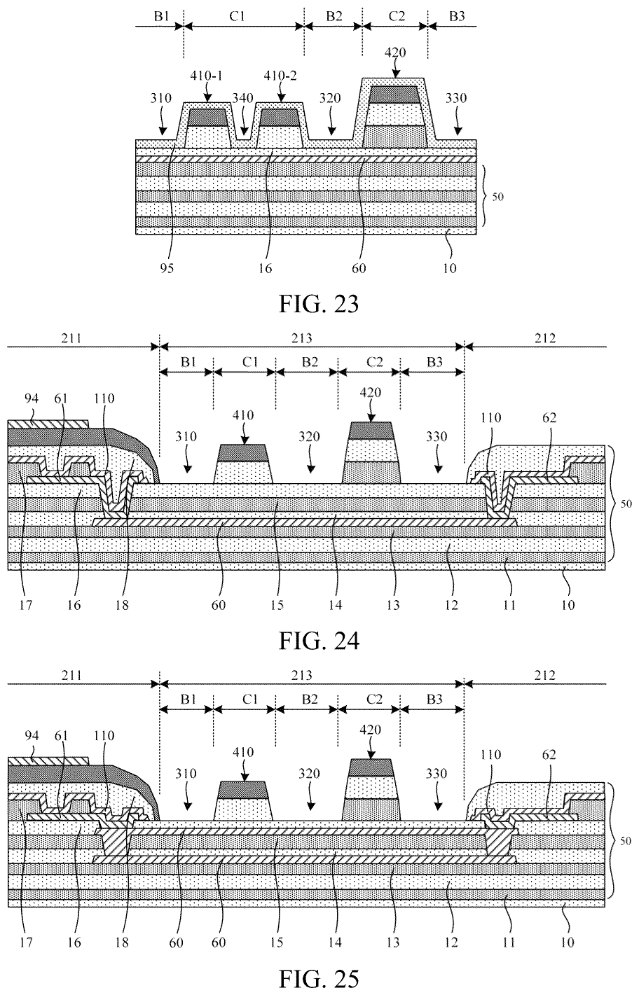

FIG. 23 is a schematic diagram of a structure of yet another display substrate according to an exemplary embodiment of the present disclosure, wherein a cross-sectional structure of an isolation dam region is illustrated. A main body structure of the display substrate of the exemplary embodiment is basically the same as that of the display substrate shown in FIG. 7, except that three isolation dams and four partition slots are disposed in the isolation dam region.

In an exemplary implementation mode, the isolation dam region may at least include a first slot region B1, a first dam region C1, a second slot region B2, a second dam region C2, and a third slot region B3 sequentially disposed along a direction away from the display region. The first slot region B1 is configured to dispose a first isolation slot 310, the second slot region B2 is configured to dispose a second isolation slot 320, the third slot region B3 is configured to dispose a third isolation slot 330, the first dam region C1 is configured to dispose a first sub-dam 410-1, a second sub-dam 410-2, and a fourth isolation slot 340, and the second dam region C2 is configured to dispose a second isolation dam 420.

In an exemplary implementation mode, the second sub-dam 410-2 may be disposed at a side of the first sub-dam 410-1 away from the display region 100, structures of the first sub-dam 410-1 and the second sub-dam 410-2 may be basically identical, including a second dam foundation and a fourth dam foundation that are stacked, the second dam foundation may be disposed in a same layer as the second planarization layer, the fourth dam foundation may be disposed in a same layer as the pixel definition layer, and the first sub-dam 410-1 and the second sub-dam 410-2 form a double-ring first isolation dam. The second isolation dam 420 may be disposed at a side of the second sub-dam 410-2 away from the display region 100 and a structure of the second isolation dam 420 may be basically the same as the aforementioned embodiments.

In an exemplary implementation mode, the first isolation slot 310 may be disposed at a side of the first sub-dam 410-1 close to the display region, the second isolation slot 320 may be disposed between the second sub-dam 410-2 and the second isolation dam 420, the third isolation slot 330 may be disposed at a side of the second isolation dam 420 away from the display region 100, and the fourth isolation slot 340 may be disposed between the first sub-dam 410-1 and the second sub-dam 410-2. An organic layer within the first isolation slot 310, the second isolation slot 320, the third isolation slot 330, and the fourth isolation slot 340 is removed to expose a surface of the sixth insulation layer 16, so that the first encapsulation layer 95 of an inorganic material is directly attached to the sixth insulation layer 16 within a partition slot.

According to the display substrate of the exemplary embodiment of the present disclosure, not only a short circuit situation may be effectively avoided and poor display of the display substrate may be effectively avoided, but also a propagation path of water vapor is blocked to a maximum extent by disposing three isolation dams and four partition slots, an encapsulation effect is improved to a maximum extent and display quality is improved.

FIG. 24 is a schematic diagram of a structure of yet another display substrate according to an exemplary embodiment of the present disclosure, wherein a cross-sectional structure of a fanout region is illustrated. A main body structure of the display substrate of the exemplary embodiment is basically the same as that of the display substrate shown in FIG. 7, except that a gate metal layer in the bonding structure layer 50 may include a second gate metal layer and the power supply connection line 60 is disposed in the second gate metal layer.

In an exemplary implementation mode, the bonding structure layer 50 may further include a first insulation layer 11, a second insulation layer 12, a third insulation layer 13, a fourth insulation layer 14, a fifth insulation layer 15, a sixth insulation layer 16, a first planarization layer 17, and a second planarization layer 18. The first insulation layer 11 is disposed on a base substrate 10, the second insulation layer 12 is disposed at a side of the first insulation layer 11 away from the base substrate, the third insulation layer 13 is disposed at a side of the second insulation layer 12 away from the base substrate, the power supply connection line 60 is disposed at a side of the third insulation layer 13 away from the base substrate, the fourth insulation layer 14 is disposed at a side of the power supply connection line 60 away from the base substrate, the fifth insulation layer 15 is disposed at a side of the fourth insulation layer 14 away from the base substrate, the sixth insulation layer 16 is disposed at a side of the fifth insulation layer 15 away from the base substrate, a first lap electrode 61 and a second lap electrode 62 are disposed at a side of the sixth insulation layer 16 away from the base substrate, the first planarization layer 17 is disposed at a side of the first lap electrode 61 and the second lap 62 away from the base substrate, a first power supply line 100 is disposed at the first planarization layer 17 away from the base substrate, and the second planarization layer 18 is disposed at a side of the first power supply line 110 away from the base substrate.

In an exemplary implementation mode, a first connection opening and a second connection opening may be disposed on the fourth insulation layer 14, the fifth insulation layer 15, and the sixth insulation layer 16 covering the power supply connection line 60, the first lap electrode 61 may be connected with a side of the power supply connection line 60 close to the display region through the first connection opening, and the second lap electrode 62 may be connected with a side of the power supply connection line away from the display region through the second connection opening.

In an exemplary implementation mode, a connection structure of the first power supply line 110 with the first lap electrode 61 and the second lap electrode 62, a structure of the first planarization layer 17, and a structure of the second planarization layer 18 may be basically the same as those of the foregoing embodiments, and will not be repeated here.

In an exemplary implementation mode, the power supply connection line 60 of the fanout region 201 may be disposed in a same layer as a second electrode plate of the display region and formed synchronously through a same patterning process.

In the exemplary embodiment, by disposing the power supply connection line on the second gate metal layer, the power supply connection line is covered with the fifth insulation layer and the sixth insulation layer, so that a short circuit situation may be effectively avoided, and poor display of the display substrate may be effectively avoided.

In one possible implementation mode, the gate metal layer in the bonding structure layer 50 may include a first gate metal layer, and the power supply connection line 60 may be disposed in the first gate metal layer. A first connection opening and a second connection opening may be disposed on the third insulation layer 13, the fourth insulation layer 14, the fifth insulation layer 15, and the sixth insulation layer 16 covering the power supply connection line 60, the first lap electrode 61 may be connected with a side of the power supply connection line 60 close to the display region through the first connection opening, and the second lap electrode 62 may be connected with a side of the power supply connection line away from the display region through the second connection opening.

FIG. 25 is a schematic diagram of a structure of yet another display substrate according to an exemplary embodiment of the present disclosure, wherein a cross-sectional structure of a fanout region is illustrated. A main body structure of the display substrate of the exemplary embodiment is basically the same as that of the display substrate shown in FIG. 7, except that a gate metal layer in the bonding structure layer 50 includes a second gate metal layer and a third gate metal layer disposed in sequence along a direction away from the base substrate, the power supply connection line 60 is disposed in the second gate metal layer and the third gate metal layer, respectively, and the power supply connection line 60 in the third gate metal layer is connected with the power supply connection line 60 in the second gate metal layer through a via to form a double-layer power supply connection line structure.

In an exemplary implementation mode, a connection structure of the first power supply line 110 with the first lap electrode 61 and the second lap electrode 62, a structure of the first planarization layer 17, and a structure of the second planarization layer 18 may be basically the same as those of the foregoing embodiments, and will not be repeated here.

In the exemplary embodiment, by disposing the power supply connection line in the second gate metal layer and the third gate metal layer, not only a short circuit situation may be effectively avoided and poor display of the display substrate may be effectively avoided, but also connection reliability may be improved.

In one possible implementation mode, the gate metal layer in the bonding structure layer 50 may include a first gate metal layer, a second gate metal layer, and a third gate metal layer disposed in sequence along a direction away from the base substrate, the power supply connection line 60 is disposed in the first gate metal layer, the second gate metal layer, and the third gate metal layer, respectively, and the power supply connection line 60 in the third gate metal layer is connected with the power supply connection line 60 in the second gate metal layer through a via, and the power supply connection line 60 in the second gate metal layer is connected with the power supply connection line 60 in the first gate metal layer through a via, thus forming a three-layer power supply connection line structure.

In another possible implementation mode, the power supply connection line 60 may be disposed in the first gate metal layer and the second gate metal layer respectively, or may be disposed in the first gate metal layer and the third gate metal layer respectively, and the present disclosure is not limited thereto.

An exemplary embodiment of the present disclosure also provides a preparation method of a display substrate. In an exemplary implementation mode, the display substrate includes a display region and a bonding region located at a side of the display region, the bonding region at least includes a fanout region and a bending region, the fanout region is located between the display region and the bending region, and the fanout region at least includes a first transition region, an isolation dam region, and a second transition region disposed along a direction away from the display region; the preparation method may include: forming a bonding structure layer on a base substrate of the fanout region, wherein the bonding structure layer at least includes a gate metal layer and a source-drain metal layer disposed at a side of the gate metal layer away from the base substrate, the gate metal layer includes any one or more of following: a first gate metal layer, a second gate metal layer, and a third gate metal layer, the source-drain metal layer includes any one or more of following: a first source-drain metal layer and a second source-drain metal layer, and a power supply connection line is disposed in the gate metal layer, a first power supply line is disposed in the source-drain metal layer, the power supply connection line is disposed in the first transition region, the isolation dam region, and the second transition region, the first power supply line is disposed in the first transition region and the second transition region, a first power supply line of the first transition region and a first power supply line of the second transition region are connected with each other through the power supply connection line.

The present disclosure also provides a display apparatus which includes the aforementioned display substrate. The display apparatus may be any product or component with a display function, such as a mobile phone, a tablet computer, a television, a display, a laptop computer, a digital photo frame, and a navigator.

Although implementation modes disclosed in the present disclosure are described as above, the described contents are only implementation modes which are used for facilitating understanding of the present disclosure, but are not intended to limit the present disclosure. Any skilled person in the art to which the present disclosure pertains may make any modification and variation in a form and details of implementation without departing from the spirit and scope of the present disclosure. However, the patent protection scope of the present disclosure should be subject to the scope defined in the appended claims.

1. A display substrate, comprising a display region and a bonding region located at a side of the display region, wherein the bonding region at least comprises a fanout region and a bending region, the fanout region is located between the display region and the bending region, the fanout region at least comprises a first transition region, an isolation dam region, and a second transition region disposed along a direction away from the display region; the fanout region comprises a bonding structure layer disposed on a base substrate, the bonding structure layer at least comprises a gate metal layer and a source-drain metal layer disposed at a side of the gate metal layer away from the base substrate, the gate metal layer comprises any one or more of following: a first gate metal layer, a second gate metal layer, and a third gate metal layer, the source-drain metal layer comprises any one or more of following: a first source-drain metal layer and a second source-drain metal layer, and a power supply connection line is disposed in the gate metal layer, a first power supply line is disposed in the source-drain metal layer, the power supply connection line is disposed in the first transition region, the isolation dam region, and the second transition region, the first power supply line is disposed in the first transition region and the second transition region, a first power supply line of the first transition region and a first power supply line of the second transition region are connected with each other through the power supply connection line.

2. The display substrate according to claim 1, wherein the bonding structure layer further comprises a first planarization layer disposed at a side of the first source-drain metal layer away from the base substrate, the first power supply line is disposed at a side of the first planarization layer away from the base substrate, the first source-drain metal layer is provided with a first lap electrode and a second lap electrode, the first lap electrode is disposed in the first transition region, the second lap electrode is disposed in the second transition region, the first power supply line of the first transition region is connected with the first lap electrode, the first lap electrode is connected with a side of the power supply connection line close to the display region, the first power supply line of the second transition region is connected with the second lap electrode, and the second lap electrode is connected with a side of the power supply connection line away from the display region.

3. The display substrate according to claim 2, wherein the bonding structure layer further comprises an inorganic insulation layer disposed at a side of the power supply connection line away from the base substrate, the inorganic insulation layer is provided with a first connection opening and a second connection opening, the first lap electrode is connected with the side of the power supply connection line close to the display region through the first connection opening, and the second lap electrode is connected with the side of the power supply connection line away from the display region through the second connection opening.

4. The display substrate according to claim 2, wherein a third connection opening is disposed on the first planarization layer, and the first power supply line of the first transition region is connected with the first lap electrode through the third connection opening.

5. The display substrate according to claim 2, wherein the first planarization layer is provided with a first partition slot, an orthographic projection of the first partition slot on the base substrate contains an orthographic projection of the isolation dam region on the base substrate, the first planarization layer at a side of the first partition slot close to the display region covers an edge of the first lap electrode at a side close to the display region, the first planarization layer at a side of the first partition slot away from the display region covers an edge of the second lap electrode at a side away from the display region, the first partition slot exposes a surface of the first lap electrode at a side away from the display region, a surface of the second lap electrode at a side close to the display region, and a surface of the inorganic insulation layer between the first lap electrode and the second lap electrode.

6. The display substrate according to claim 5, wherein the first power supply line of the first transition region is lapped with the first lap electrode exposed in the first partition slot.

7. The display substrate according to claim 6, wherein the first power supply line of the first transition region covers an edge of the first lap electrode at a side away from the display region.

8. The display substrate according to claim 5, wherein the first power supply line of the second transition region is lapped with the second lap electrode exposed in the first partition slot.

9. The display substrate according to claim 8, wherein the first power supply line of the second transition region covers an edge of the second lap electrode at a side close to the display region.

10. The display substrate according to claim 2, wherein the bonding structure layer further comprises a second planarization layer disposed at a side of the second source-drain metal layer away from the base substrate, the second planarization layer is provided with a second partition slot, an orthographic projection of the second partition slot on the base substrate contains an orthographic projection of the isolation dam region on the base substrate, the second planarization layer at a side of the second partition slot close to the display region covers an edge of the first power supply line of the first transition region at a side away from the display region, and the second planarization layer at a side of the second partition slot away from the display region covers an edge of the first power supply line of the second transition region at a side close to the display region.

11. The display substrate according to claim 1, wherein the isolation dam region is provided with at least one isolation dam and at least one partition slot, the isolation dam is disposed at a side of the inorganic insulation layer away from the display region, the partition slot is disposed at a side of the isolation dam close to the display region or at a side of the isolation dam away from the display region, and the partition slot exposes a surface of the inorganic insulation layer.

12. The display substrate according to claim 1, wherein on a plane perpendicular to the display substrate, the display substrate at least comprises a first gate metal layer, a second gate metal layer, a third gate metal layer, a first source-drain metal layer, and a second source-drain metal layer that are sequentially disposed on the base substrate, the power supply connection line is disposed in one or more of the first gate metal layer, the second gate metal layer, and the third gate metal layer, and the first power supply line is disposed in the second source-drain metal layer.

13. The display substrate according to claim 1, wherein on a plane perpendicular to the display substrate, the display substrate at least comprises a first gate metal layer, a second gate metal layer, a third gate metal layer, and a first source-drain metal layer that are sequentially disposed on the base substrate, the power supply connection line is disposed in one or more of the first gate metal layer, the second gate metal layer, and the third gate metal layer, and the first power supply line is disposed in the first source-drain metal layer.

14. A display apparatus, comprising a display substrate according to claim 1.

15. A preparation method of a display substrate, wherein the display substrate comprises a display region and a bonding region located at a side of the display region, the bonding region at least comprises a fanout region and a bending region, the fanout region is located between the display region and the bending region, and the fanout region at least comprises a first transition region, an isolation dam region, and a second transition region disposed along a direction away from the display region; the preparation method comprises:
forming a bonding structure layer on a base substrate of the fanout region, wherein the bonding structure layer at least comprises a gate metal layer and a source-drain metal layer disposed at a side of the gate metal layer away from the base substrate, the gate metal layer comprises any one or more of following: a first gate metal layer, a second gate metal layer, and a third gate metal layer, the source-drain metal layer comprises any one or more of following: a first source-drain metal layer and a second source-drain metal layer, and a power supply connection line is disposed in the gate metal layer, a first power supply line is disposed in the source-drain metal layer, the power supply connection line is disposed in the first transition region, the isolation dam region, and the second transition region, the first power supply line is disposed in the first transition region and the second transition region, a first power supply line of the first transition region and a first power supply line of the second transition region are connected with each other through the power supply connection line.

16. The display substrate according to claim 2, wherein on a plane perpendicular to the display substrate, the display substrate at least comprises a first gate metal layer, a second gate metal layer, a third gate metal layer, a first source-drain metal layer, and a second source-drain metal layer that are sequentially disposed on the base substrate, the power supply connection line is disposed in one or more of the first gate metal layer, the second gate metal layer, and the third gate metal layer, and the first power supply line is disposed in the second source-drain metal layer;
or,
on a plane perpendicular to the display substrate, the display substrate at least comprises a first gate metal layer, a second gate metal layer, a third gate metal layer, and a first source-drain metal layer that are sequentially disposed on the base substrate, the power supply connection line is disposed in one or more of the first gate metal layer, the second gate metal layer, and the third gate metal layer, and the first power supply line is disposed in the first source-drain metal layer.

17. The display substrate according to claim 3, wherein on a plane perpendicular to the display substrate, the display substrate at least comprises a first gate metal layer, a second gate metal layer, a third gate metal layer, a first source-drain metal layer, and a second source-drain metal layer that are sequentially disposed on the base substrate, the power supply connection line is disposed in one or more of the first gate metal layer, the second gate metal layer, and the third gate metal layer, and the first power supply line is disposed in the second source-drain metal layer;
or,
on a plane perpendicular to the display substrate, the display substrate at least comprises a first gate metal layer, a second gate metal layer, a third gate metal layer, and a first source-drain metal layer that are sequentially disposed on the base substrate, the power supply connection line is disposed in one or more of the first gate metal layer, the second gate metal layer, and the third gate metal layer, and the first power supply line is disposed in the first source-drain metal layer.

18. The display substrate according to claim 4, wherein on a plane perpendicular to the display substrate, the display substrate at least comprises a first gate metal layer, a second gate metal layer, a third gate metal layer, a first source-drain metal layer, and a second source-drain metal layer that are sequentially disposed on the base substrate, the power supply connection line is disposed in one or more of the first gate metal layer, the second gate metal layer, and the third gate metal layer, and the first power supply line is disposed in the second source-drain metal layer;
or,
on a plane perpendicular to the display substrate, the display substrate at least comprises a first gate metal layer, a second gate metal layer, a third gate metal layer, and a first source-drain metal layer that are sequentially disposed on the base substrate, the power supply connection line is disposed in one or more of the first gate metal layer, the second gate metal layer, and the third gate metal layer, and the first power supply line is disposed in the first source-drain metal layer.

19. The display substrate according to claim 5, wherein on a plane perpendicular to the display substrate, the display substrate at least comprises a first gate metal layer, a second gate metal layer, a third gate metal layer, a first source-drain metal layer, and a second source-drain metal layer that are sequentially disposed on the base substrate, the power supply connection line is disposed in one or more of the first gate metal layer, the second gate metal layer, and the third gate metal layer, and the first power supply line is disposed in the second source-drain metal layer;
or,
on a plane perpendicular to the display substrate, the display substrate at least comprises a first gate metal layer, a second gate metal layer, a third gate metal layer, and a first source-drain metal layer that are sequentially disposed on the base substrate, the power supply connection line is disposed in one or more of the first gate metal layer, the second gate metal layer, and the third gate metal layer, and the first power supply line is disposed in the first source-drain metal layer.

20. The display substrate according to claim 11, wherein on a plane perpendicular to the display substrate, the display substrate at least comprises a first gate metal layer, a second gate metal layer, a third gate metal layer, a first source-drain metal layer, and a second source-drain metal layer that are sequentially disposed on the base substrate, the power supply connection line is disposed in one or more of the first gate metal layer, the second gate metal layer, and the third gate metal layer, and the first power supply line is disposed in the second source-drain metal layer;
or,
on a plane perpendicular to the display substrate, the display substrate at least comprises a first gate metal layer, a second gate metal layer, a third gate metal layer, and a first source-drain metal layer that are sequentially disposed on the base substrate, the power supply connection line is disposed in one or more of the first gate metal layer, the second gate metal layer, and the third gate metal layer, and the first power supply line is disposed in the first source-drain metal layer.
